(19) United States
(12) Patent Application Publication
(10) Pub. No.: US 2025/0370364 A1
(43) Pub. Date: Dec. 4, 2025

(54) LIGHT EMITTING DEVICE AND IMAGE FORMING APPARATUS

(71) Applicant: CANON KABUSHIKI KAISHA, Tokyo (JP)

(72) Inventor: Mizuki NAGASAKI, Kanagawa (JP)

(21) Appl. No.: 19/211,709

(22) Filed: May 19, 2025

(30) Foreign Application Priority Data
May 30, 2024 (JP) 2024-088277

(51) Int. Cl. G03G 15/04; B41J 2/45; B41J 2/47; G03G 15/043; H10B 10/00; H10K 59/122; H10K 59/131

(52) U.S. Cl. CPC G03G 15/04036; B41J 2/45; B41J 2/47; G03G 15/043; H10B 10/12; H10K 59/122; H10K 59/131

(57) ABSTRACT

A light emitting device is provided. The light emitting device includes, on a rectangular substrate having long sides in a row direction and shot sides in a column direction, pixels arranged to form rows and columns and a scanning circuit. Each of the pixels includes a light emitting element and a driving circuit configured to drive the light emitting element, the scanning circuit includes data holding circuits provided so as to respectively correspond to the columns, each data holding circuit includes memory circuits each configured to hold data for controlling the driving circuits arranged in the pixels in a corresponding column, and the memory circuits in each data holding circuit include a first memory circuit and a second memory circuit arranged to align in the row direction.

### BACKGROUND

### Field of the Technology

The present disclosure relates to a light emitting device and an image forming apparatus.

### Description of the Related Art

There is proposed a print head (OLED-PH) for an image forming apparatus, which uses an organic light emitting diode (OLED) as a light emitting source. Japanese Patent Laid-Open No. 2022-162410 describes a light emitting device in which an OLED and a driving transistor for driving the OLED are formed on one substrate. Since the OLED and the driving transistor can be formed on the same substrate, miniaturization and cost reduction are possible.

### SUMMARY

In Japanese Patent Laid-Open No. 2022-162410, a data holding circuit configured to hold data for controlling light emission and non-light emission of each OLED is arranged. It is considered that the data holding circuit requires memory circuits for holding data, each of which is in a one-to-one correspondence with the OLED. In Japanese Patent Laid-Open No. 2022-162410, no consideration is given to the arrangement of memory circuits.

Some embodiments of the present disclosure provide a technique advantageous in miniaturization of a light emitting device.

According to some embodiments, a light emitting device that comprises, on a rectangular substrate having long sides in a row direction and shot sides in a column direction, pixels arranged to form rows and columns and a scanning circuit, wherein each of the pixels includes a light emitting element and a driving circuit configured to drive the light emitting element, the scanning circuit includes data holding circuits provided so as to respectively correspond to the columns, each data holding circuit includes memory circuits each configured to hold data for controlling the driving circuits arranged in the pixels in a corresponding column, and the memory circuits in each data holding circuit include a first memory circuit and a second memory circuit arranged to align in the row direction, is provided.

Further features of the various embodiments will become apparent from the following description of embodiments with reference to the attached drawings. The following description of embodiments are described by way of example.

### BRIEF DESCRIPTION OF THE DRAWINGS

FIG. 1 is a sectional view showing an example of the arrangement of a light emitting device according to an embodiment;

FIG. 2 is a block diagram showing an example of the arrangement of the light emitting device shown in FIG. 1;

FIG. 3 is a view showing an example of the arrangement of a driving circuit of the light emitting device shown in FIG. 1;

FIG. 4 is a view showing an example of the connection between the driving circuit and a scanning circuit of the light emitting device shown in FIG. 1;

FIG. 5 is a timing chart showing an example of the operation of the operation circuit of the light emitting device shown in FIG. 1;

FIG. 6 is a view showing an example of the arrangement of a memory circuit of the light emitting device shown in FIG. 1;

FIG. 7 is a view showing an example of the arrangement of a circuit block of the light emitting device shown in FIG. 1;

FIG. 8 is a view showing an example of the arrangement of the driving circuit and the scanning circuit of the light emitting device shown in FIG. 1;

FIG. 9 is a view showing an example of the arrangement of the driving circuit and the scanning circuit of the light emitting device shown in FIG. 1;

FIG. 10 is a view showing an example of the arrangement of the driving circuit and the scanning circuit of the light emitting device shown in FIG. 1;

FIG. 11 is a view showing details of the arrangement example shown in FIG. 10;

FIG. 12 is a view showing an example of the connection between the driving circuit and the scanning circuit of the light emitting device shown in FIG. 1;

FIG. 13 is a view showing an example of the arrangement of the driving circuit and the scanning circuit of the light emitting device shown in FIG. 1;

FIG. 14 is a view showing details of the arrangement example shown in FIG. 13;

FIG. 15 is a sectional view showing an example of the arrangement of the light emitting device according to the embodiment;

FIGS. 16A and 16B are sectional views showing an example of the arrangement of a pixel of the light emitting device according to the embodiment;

FIGS. 17A to 17C are views showing an example of an image forming apparatus using the light emitting device according to the embodiment;

FIG. 18 is a view showing an example of a display apparatus using the light emitting device according to the embodiment;

FIG. 19 is a view showing an example of a photoelectric conversion apparatus using the light emitting device according to the embodiment;

FIG. 20 is a view showing an example of electronic equipment using the light emitting device according to the embodiment;

FIGS. 21A and 21B are views each showing an example of a display apparatus using the light emitting device according to the embodiment;

FIG. 22 is a view showing an example of an illumination apparatus using the light emitting device according to the embodiment;

FIG. 23 is a view showing an example of a moving body using the light emitting device according to the embodiment; and

FIGS. 24A and 24B are views each showing an example of a wearable device using the light emitting device according to the embodiment.

### DESCRIPTION OF THE EMBODIMENTS

Example embodiments of the present disclosure will be described hereinafter in detail, with reference to the accompanying drawings. It is to be understood that the following embodiments are not intended to limit the claims of the present disclosure, and that not all of the combinations of the aspects that are described according to the following embodiments are necessarily required with respect to the means to solve the issues according to the present disclosure. Further, in the accompanying drawings, the same or similar configurations are assigned the same reference numerals, and redundant descriptions are omitted.

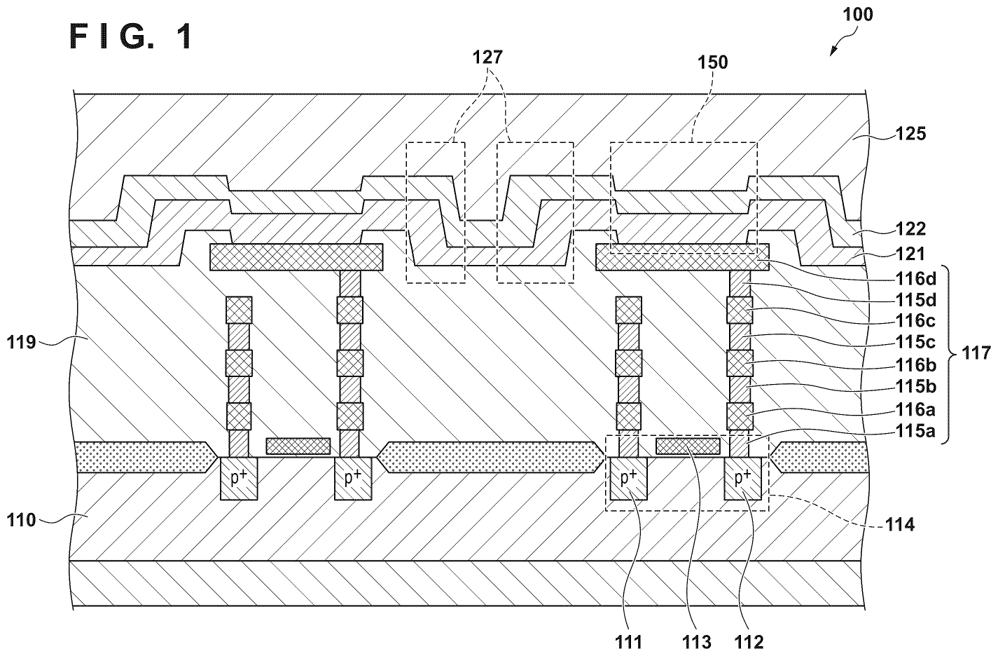

With reference to FIGS. 1 to 14, a light emitting device according to an embodiment of the present disclosure will be described. In the following description, an example will be described in which an organic light emitting diode (OLED) is used as a light emitting element arranged in the light emitting device. However, the present disclosure is not limited to the light emitting device using the OLED, and is also applicable to light emitting devices including current-driven light emitting elements in general.

FIG. 1 is a sectional view showing an example of the arrangement of a light emitting device 100 according to this embodiment. FIG. 1 shows a section including a light emitting element 150 and a transistor 114 connected to the light emitting element 150. The light emitting element 150 and the transistor 114 constitute a pixel, and the transistor 114 can form a part of a driving circuit to be described later. The transistor 114 may be provided in, for example, a substrate 110 made of a semiconductor such as silicon. The transistor 114 is formed by including a gate 113, a drain 112, and a source 111.

The drain 112 of the transistor 114 and the light emitting element 150 are connected by a wiring pattern 117. The wiring pattern 117 can include contact plugs 115a to 115d and conductive patterns 116a to 116d. An insulating layer 119 is provided between the wiring patterns 117. It can also be said that the wiring pattern 117 is arranged in the insulating layer 119. In FIG. 1, the insulating layer 119 is shown as one layer, but the insulating layer 119 may have a stacked structure in which layers are stacked.

The light emitting element 150 is formed by including the conductive pattern 116d, an organic compound layer 121 including a light emitting layer, and an electrode 122. The conductive pattern 116d is an electrode independent for each light emitting element 150 (pixel), and can also be called a lower electrode or the like. The electrode 122 may be shared by the light emitting elements 150 (pixels), and is a transparent electrode. Since the electrode 122 is transparent, light from the organic compound layer 121 can be extracted to the outside. A protection layer 125 is provided on the electrode 122 to suppress deterioration of the light emitting element 150 (organic compound layer 121). In the light emitting device 100, a combination of the light emitting element 150 and the transistor 114 (driving circuit) can be repeatedly arranged in the row direction and the column direction.

A structure 127 having a large stepped portion in a layer immediately below the organic compound layer 121 is formed between the respective light emitting elements 150. With the structure 127, the electrode 122 is formed to provide electrical connection while the organic compound layer 121 is electrically isolated for each light emitting element 150 (pixel).

The connection with the electrode (the source 111 or the drain 112) included in the transistor 114 is not limited to the arrangement shown in FIG. 1. In accordance with the polarity of the conductive pattern 116d (light emitting element 150) or the polarity of the transistor 114, the source 111 and drain 112 of the transistor 114 may be interchanged. It is only required that one of the source 111 and drain 112 of the transistor 114 is electrically connected to the light emitting element 150.

The transistor 114 is not limited to be provided in the substrate 110 made of a semiconductor such as single-crystal silicon. For example, the transistor 114 may be a thin film transistor (TFT) which is formed in an active layer using a semiconductor formed on the surface of an insulating substrate made of glass, a plastic, or the like. Examples of the material for the active layer are single-crystal silicon, non-single-crystal silicon such as amorphous silicon or microcrystal silicon, and a non-single-crystal oxide semiconductor such as indium zinc oxide or indium gallium zinc oxide.

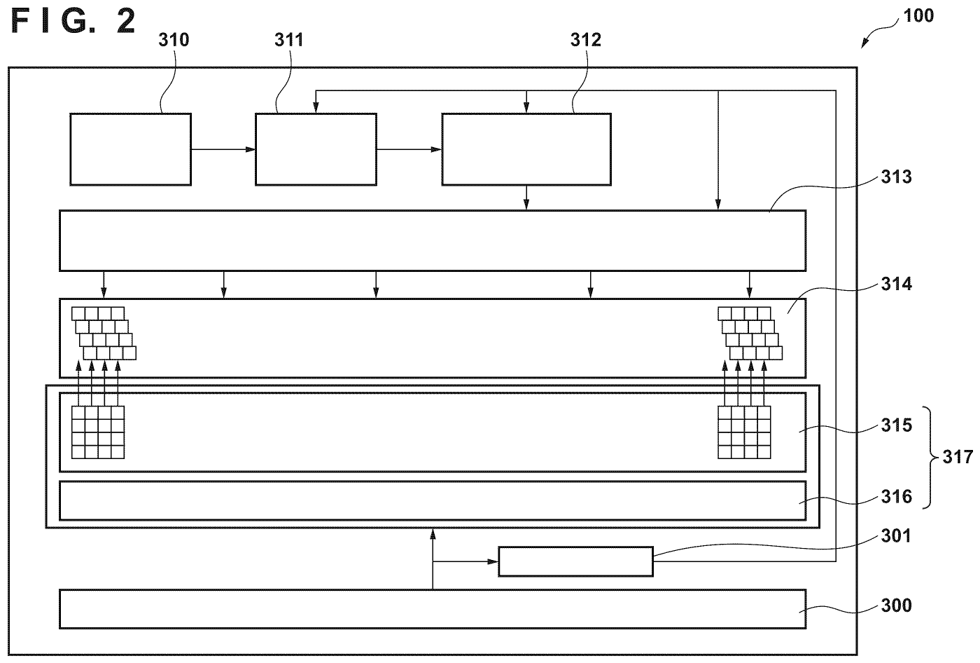

FIG. 2 shows a circuit block showing an example of the arrangement of the light emitting device 100 according to this embodiment. The light emitting device 100 includes an interface circuit 300, a register 301, a reference current generation circuit 310, a programmable current source 311, a bias current source 312, a current control circuit 313, a pixel driving unit 314, and a scanning circuit 317. The scanning circuit 317 is formed by including a data holding unit 315 and a column selection unit 316.

The interface circuit 300 receives mode information for accessing the power supply or the register from outside the light emitting device 100, information concerning image data, or the like, and outputs a data signal to the register 301 or the scanning circuit 317. The programmable current source 311 uses the output current of the reference current generation circuit 310 as a reference, and outputs, to the bias current source 312, a current corresponding to a digital value supplied from the register 301. The driving current for the pixel driving unit 314 is controlled by the set value of the register 301. The bias current source 312 supplies, to the current control circuit 313, an output current corresponding to the set value set by the register 301. The current control circuit 313 generates the bias voltage of the pixel driving unit 314.

The data holding unit 315 of the scanning circuit 317 is formed by including data holding circuits. The data holding circuit holds data corresponding to each light emitting element 150, and controls light emission and non-light emission of the light emitting element 150. The column selection unit 316 of the scanning circuit 317 is formed by including column selection circuits. Based on the data signal from the interface circuit 300, the column selection unit 316 selects the holding circuit to write data out of the data holding circuits and, as a result, controls the light emission and non-light emission timings of the light emitting element 150. The pixel driving unit 314 is formed by including driving circuits. Each driving circuit is connected to the light emitting element 150. The driving current for each driving circuit is decided by the bias voltage supplied from the current control circuit 313, and the driving circuit controls light emission or non-light emission of the light emitting element 150 by a signal supplied from the data holding unit 315. Details of the pixel driving unit 314 and the scanning circuit 317 will be described later.

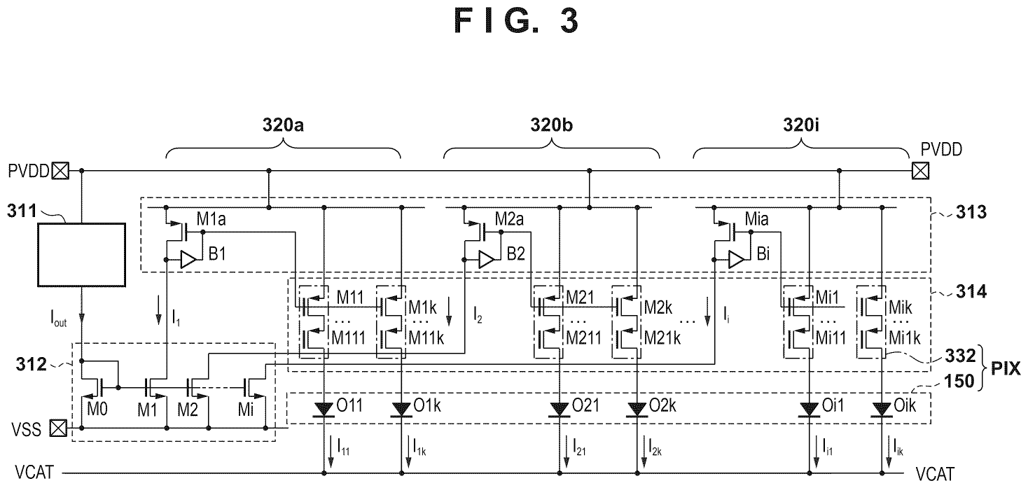

FIG. 3 is a view showing an example of the arrangement of the bias current source 312, the current control circuit 313, the pixel driving unit 314, and the light emitting element 150. A light emission current adjusting method and light emission control for the light emitting element 150 will be described below.

As shown in FIG. 3, driving circuits 332 are arranged in the pixel driving unit 314. Light emitting elements O11 to Oik are arranged as the light emitting elements 150. Each of the driving circuits 332 is connected to the corresponding light emitting element O to drive the light emitting element O. A pixel PIX is formed by including the corresponding driving circuit 332 and light emitting element O. The driving circuits 332 include transistors M11 to Mik for controlling currents flowing through the light emitting elements O11 to Oik, and transistors M111 to Mi1k for controlling light emission or non-light emission of the light emitting elements O11 to Oik. From the data holding unit 315 holding data corresponding to each light emitting element 150, a signal corresponding to the data is supplied to the control terminal of corresponding one of the transistors M111 to Mi1k. Thus, light emission or non-light emission of each of the light emitting elements O11 to Oik is controlled. The transistors M11 to Mik are series-connected to the corresponding transistors M111 to Mi1k, respectively. Similarly, the transistors M111 to Mi1k are series-connected to the corresponding light emitting elements O11 to Oik, respectively. Each of the transistors M111 to Mi1k corresponds to the transistor 114 shown in FIG. 1.

An output current Iₒᵤₜ of the programmable current source 311 is connected to the drain terminal of a transistor M0 constituting the bias current source 312. The transistor M0 is diode-connected, and a potential Vbn decided by the current Iₒᵤₜ is commonly applied to the gate terminals of transistors M0 to Mi constituting the bias current source 312.

The pixels PIX arranged in the light emitting device 100 are divided into circuit blocks 320 each including a predetermined number of the pixels PIX. In a circuit block 320a, the drain terminal of a transistor M1a constituting the current control circuit 313 and the drain terminal of the transistor M1 constituting the bias current source 312 are connected in series. The gate terminal of the transistor M1a is connected to the drain terminal of the transistor M1a via a buffer B1. The buffer B1 is, for example, a voltage buffer having a gain of 1, and has a role of absorbing fluctuations in the gate potentials of the transistors M11 to M1k caused by the light emission control operations of the driving circuits 332. The transistor M1a is diode-connected via the buffer B1, and a potential Vbp1 decided by a current I₁ is commonly applied to the gate terminals of the transistors M11 to M1k each constituting the driving circuit 332 of the pixel PIX.

The gate-source voltage is the same among the transistors M11 to M1k, so that the same driving current can be supplied to the light emitting elements O11 to O1k arranged in the circuit block 320a. That is, the transistors M11 to M1k function as constant current sources. Although not shown in FIG. 3, a driving voltage is applied to the gate terminals of the transistors M111 to M11k from the data holding circuit arranged in the data holding unit 315. Thus, whether to supply a current to each of the light emitting elements O11 to O1k is controlled. As a result, light emission or non-light emission of each of the light emitting elements O11 to O1k is controlled. That is, the transistors M111 to M11k function as switches.

If the driving circuit 332 is influenced by fluctuations in the power supply potential, the current for driving the light emitting element O changes, which can cause, for example, unevenness in an output image of an image forming apparatus including the light emitting device 100. In the bias current source 312, the transistor M0 and the transistors M1 to Mi are arranged close to each other to form a current mirror circuit. This forms an arrangement that is less influenced by fluctuations in power supply lines PVDD and VSS. As a result, by employing the circuit arrangement according to this embodiment, it is possible to suppress unevenness in an output image of the image forming apparatus including the light emitting device 100. Similarly, in the circuit block 320a, the transistor M1a and the transistors M11 to M1k are arranged close to each other to form a current mirror circuit. This can suppress unevenness in an output image of the image forming apparatus including the light emitting device 100.

Each of circuit blocks 320b to 320i has an arrangement similar to the arrangement of the circuit block 320a. That is, the light emitting elements O21 to O2k are driven to emit light by the driving circuits 332 including the transistors M21 to M2k and the transistors M211 to M21k. The light emitting elements Oi1 to Oik are driven to emit light by the driving circuits 332 including the transistors Mi1 to Mik and the transistors Mi11 to Mi1k.

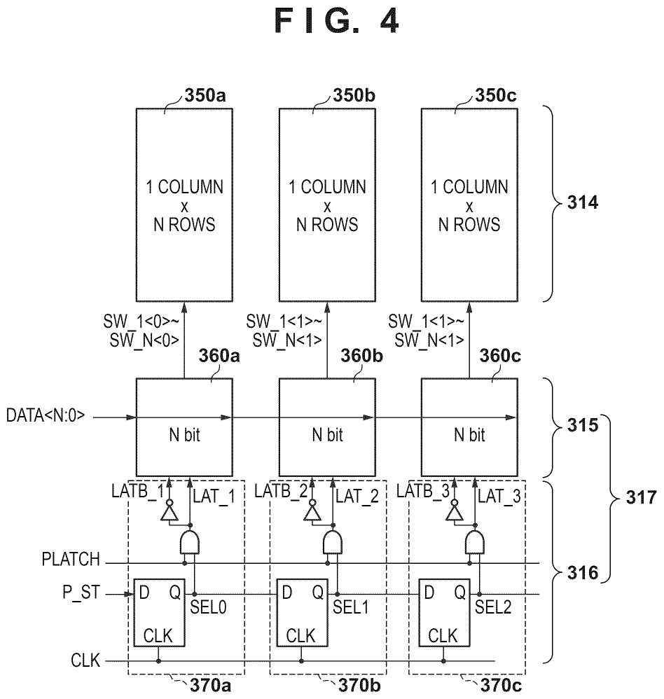

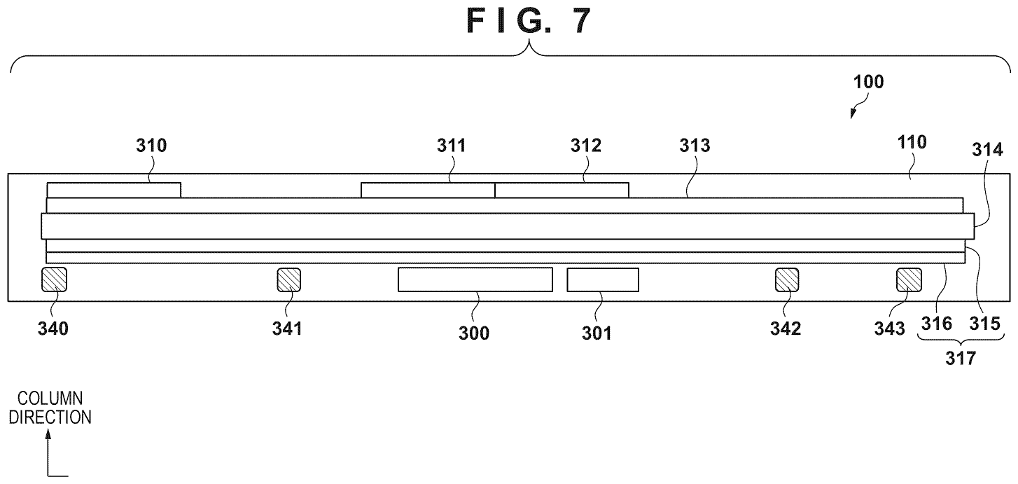

FIG. 4 shows an example of the arrangement of the pixel driving unit 314 corresponding to the light emitting elements O in N rows and three columns, and the column selection unit 316 and the data holding unit 315 constituting the scanning circuit 317. As will be described later with reference to FIG. 7, the pixels PIX are arranged to form rows and columns on the rectangular substrate 110 having long sides in the row direction and short sides in the column direction. The circuit shown in FIG. 4 is a circuit corresponding to the pixels PIX in N rows and three columns among the pixels PIX.

Each of column driving circuits 350a to 350c is formed by N driving circuits 332 respectively corresponding to N light emitting elements O arranged in the pixels PIX in each column. Each of the column driving circuits 350a to 350c drives N light emitting elements O arranged in each column.

The data holding unit 315 of the scanning circuit 317 includes data holding circuits 360a to 360c provided so as to respectively correspond to the columns in which the pixels PIX are arranged. As will be described later, each of the data holding circuits 360a to 360c includes memory circuits 400 that respectively hold data for controlling the driving circuits 332 arranged in the pixels PIX in the corresponding column. The data holding circuits 360a to 360c are electrically connected to the corresponding column driving circuits 350a to 350c, respectively, and control the driving circuits 332 arranged in the column driving circuits 350a to 350c.

The column selection unit 316 of the scanning circuit 317 includes column selection circuits 370a to 370c. Each of the column selection circuits 370a to 370c selects the data holding circuit 360 to write data for controlling the column driving circuit 350. The column selection circuit 370 is formed by including a flip-flop circuit and a logic element.

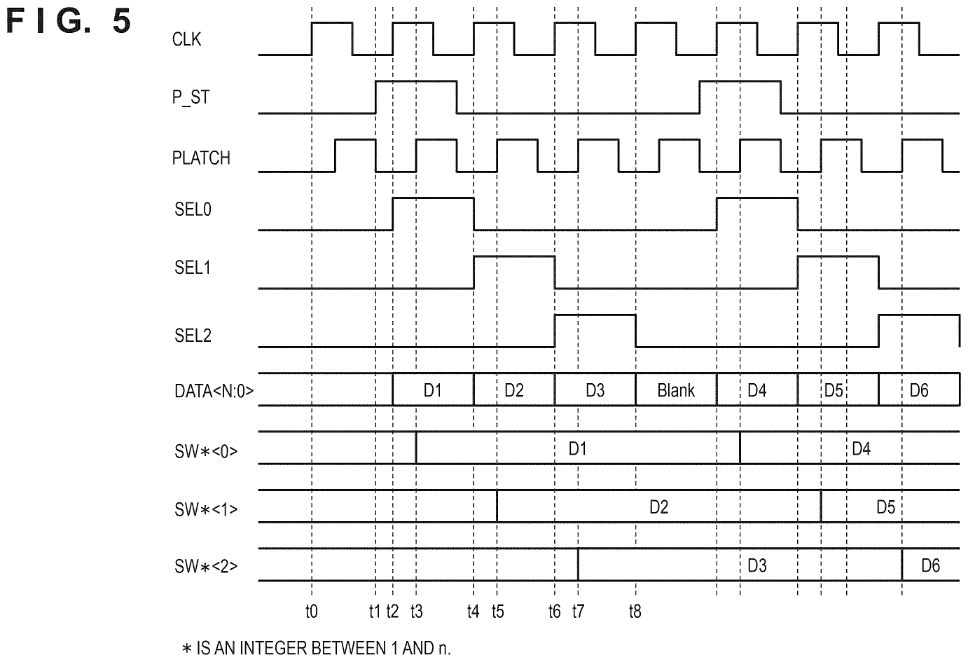

The interface circuit 300 supplies the scanning circuit 317 with a start pulse P_ST, a latch pulse PLATCH, and a data signal DATA<N:0> for controlling light emission or non-light emission of the light emitting element O. FIG. 5 exemplarily shows the operation of the scanning circuit 317 including the data holding unit 315 and the column selection unit 316. From time to, a clock signal CLK starts to be supplied. The interface circuit 300 supplies, to the column selection unit 316, the start pulse P_ST which becomes active level at time t1. The column selection circuits 370a to 370c arranged in the column selection unit 316 generate column selection signals SEL0 to SEL2, which do not overlap each other, by sequentially transferring pulse signals to the subsequent stages in synchronization with the clock signal CLK.

During the period from time t2 to time t4, the column selection signal SEL0 is at active level, and the latch pulse PLATCH becomes active level at time t3. The data holding circuit 360a of the data holding unit 315 obtains and holds a value D1 of the data signal DATA<N:0> at time t3. In accordance with the data D1 held by the data holding circuit 360a, each driving circuit 332 arranged in the column driving circuit 350a controls light emission of the corresponding light emitting element O.

During the period from time t4 to time t6, the column selection signal SEL1 is at active level, and the latch pulse PLATCH becomes active level at time t5. The data holding circuit 360b of the data holding unit 315 obtains and holds a value D2 of the data signal DATA<N:0> at time t5. In accordance with the data D2 held by the data holding circuit 360b, each driving circuit 332 arranged in the column driving circuit 350b controls light emission of the corresponding light emitting element O.

During the period from time t6 to time t8, the column selection signal SEL2 is at active level, and the latch pulse PLATCH becomes active level at time t7. The data holding circuit 360c of the data holding unit 315 obtains and holds a value D3 of the data signal DATA<N:0> at time t7. In accordance with the data D3 held by the data holding circuit 360c, each driving circuit 332 arranged in the column driving circuit 350c controls light emission of the corresponding light emitting element O. Subsequently, the above-described operations can be repeated in a similar manner.

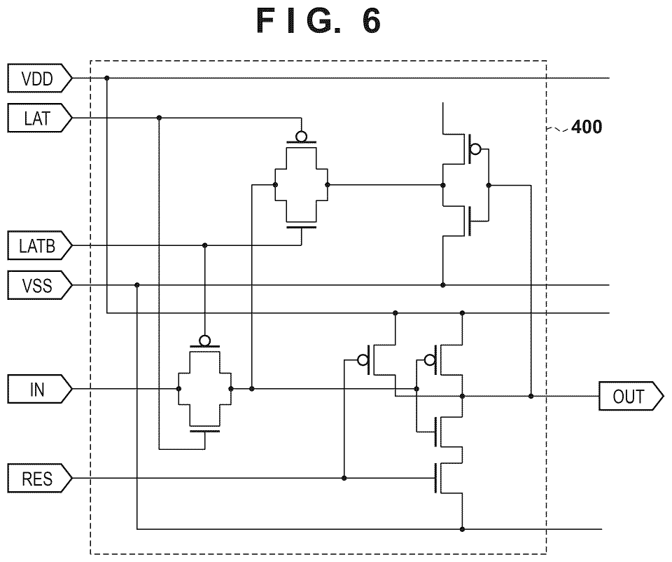

The memory circuits 400 are arranged in each of the data holding circuits 360a to 360c. A latch circuit shown in FIG. 6 is an example of the memory circuit 400. The latch circuit shown in FIG. 6 is a latch circuit having a reset function and using five NMOS transistors and five PMOS transistors. Since one latch circuit functions as one memory circuit 400, N latch circuits (memory circuits 400) are required to hold data for controlling N light emitting elements O.

FIG. 7 is a view showing an example of the arrangement of the circuit block shown in FIG. 2. The respective elements constituting the light emitting device 100 are arranged on the rectangular substrate 110 having long sides in the row direction and short sides in the column direction. In addition to the components shown in FIG. 2, FIG. 7 shows pads 340 to 343 for external connection, which are connected to the interface circuit 300.

In the pixel driving unit 314, M driving circuits 332 are arranged at a predetermined resolution pitch in the row direction as the longitudinal direction. Furthermore, with M driving circuits 332 in one row, N driving circuits 332 (for N rows) are arranged at a predetermined resolution pitch in the column direction as the lateral direction. The light emitting element O is arranged on the upper layer of each driving circuit 332.

The column selection unit 316 and the data holding unit 315 constituting the scanning circuit 317 are arranged along the row direction of the light emitting device 100. Therefore, the scanning circuit 317 occupies a large area in the light emitting device 100. Reducing the area occupied by the column selection unit 316 and the data holding unit 315 reduces the area of the light emitting device 100. In the rectangular light emitting device 100, the size in the row direction can be decided by the resolution pitch and the number of the pixels PIX arranged therein. On the other hand, reducing the size in the column direction as the lateral direction by reducing the area of the scanning circuit 317 or the like significantly contributes to improvement in yield of the light emitting devices 100 obtained from one substrate. Hence, a significant cost reduction effect can be obtained by reducing the size in the column direction.

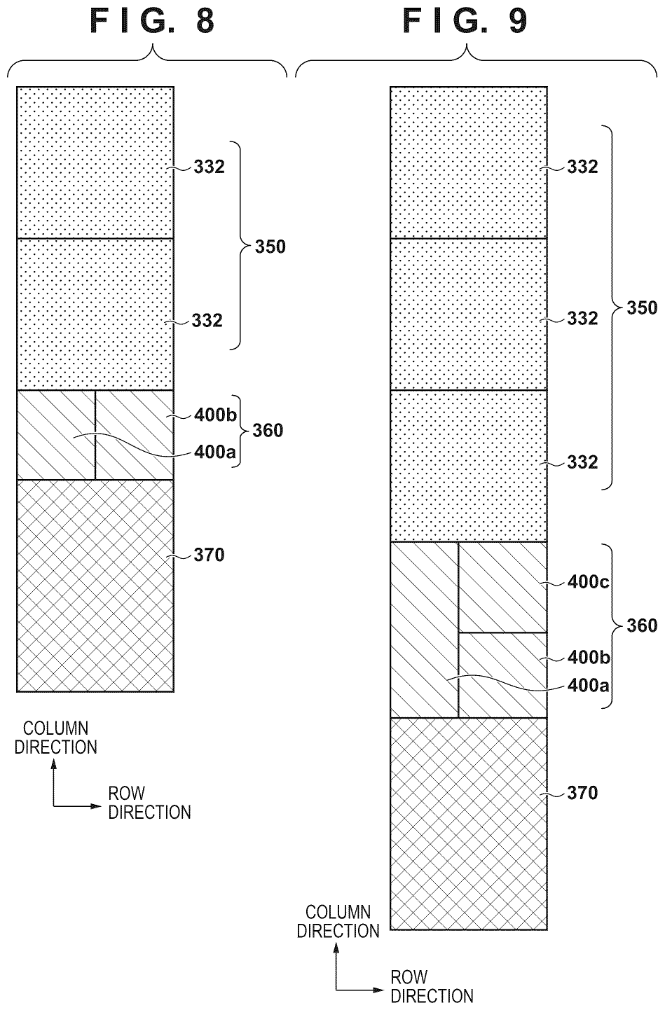

FIG. 8 shows an example of the arrangement of the column driving circuit 350 corresponding to the pixels PIX arranged in one column, the data holding circuit 360, and the column selection circuit 370. The arrangement shown in FIG. 8 is an arrangement example in which two rows of the pixels PIX are arranged in one column. In each column in which the pixels PIX are arranged, the data holding circuit 360 corresponding to each column is arranged between the driving circuit 332 (column driving circuit 350) and the column selection circuit 370.

Two driving circuits 332 are arranged in the column driving circuit 350. The corresponding light emitting elements O are arranged at positions overlapping the driving circuits 332, thereby forming two rows of pixels PIX. The driving circuits 332 are arranged corresponding to the light emitting elements O of the pixels PIX forming one column, and therefore can be arranged along the column direction as shown in FIG. 8.

In the data holding circuit 360, two memory circuits 400a and 400b are arranged to hold data for controlling the two driving circuits 332. In this case, the memory circuits 400a and 400b are arranged to align in the row direction as shown in FIG. 8. In a case of the light emitting device 100 used in an image forming apparatus or the like, the light emitting element O has a size (42 μm to 5.3 μm) corresponding to the resolution of the light emitting device 100, for example, 600 dpi to 4800 dpi. The arrangement interval between the driving circuits 332 (column driving circuits 350) in the row direction is generally approximately the same as the arrangement interval between the light emitting elements O. On the other hand, in a case of the light emitting device 100 using a semiconductor substrate made of silicon or the like, elements such as transistors can be arranged in a layout finer than the arrangement interval between the driving circuits 332 (column driving circuits 350). Accordingly, the length of the memory circuit 400 in the row direction can be made smaller than the length decided by the arrangement interval of the driving circuits 332 (column driving circuits 350) in the row direction. It can also be said that the length of the driving circuit 332 (column driving circuit 350) in the row direction is larger than the length of the memory circuit 400 in the row direction, among the memory circuits 400, arranged corresponding to each driving circuit 332 (column driving circuit 350). Hence, by arranging the memory circuits 400a and 400b in the row direction for the column driving circuit 350 in one column, the length of the data holding circuit 360 in the column direction can be made smaller than in a case of arranging the memory circuits 400a and 400b in the column direction.

By arranging the memory circuits 400a and 400b in the row direction in this manner, the size of the light emitting device 100 can be reduced. Thus, more light emitting devices 100 can be obtained from one substrate. As a result, an effect of suppressing the manufacturing cost of the light emitting device 100 can be obtained.

FIG. 9 shows an example of the arrangement of the column driving circuit 350, the data holding circuit 360, and the column selection circuit 370, in which three rows of the pixels PIX are arranged in one column. Three driving circuits 332 corresponding to the number of the pixels PIX arranged in one column are arranged in the column driving circuit 350. The driving circuits 332 can be arranged along the column direction, as in the arrangement shown in FIG. 8. In the data holding circuit 360, three memory circuits 400a to 400c are arranged to hold data for controlling the three driving circuits 332.

In the driving circuits 332 arranged in one column, there is a need to align the driving timings of the corresponding light emitting elements O. This is because, if the light emission timings of the light emitting elements O are not aligned, the light emission time changes among the pixels PIX, which can affect the quality of an image formed by the image forming apparatus including the light emitting device 100. Therefore, the data holding circuits 360 that supply signals for controlling the driving circuits 332 may be arranged in the row direction at approximately the same arrangement interval as the column driving circuits 350.

In the arrangement shown in FIG. 9, the memory circuits 400b and 400c are arranged to align in the column direction. The memory circuits 400a and 400b are arranged to align in the row direction. Similarly, the memory circuits 400a and 400c are arranged to align in the row direction. In this case, the outer edge shape of the memory circuit 400a is different from the outer edge shapes of the memory circuits 400b and 400c in a planar view. The outer edge shape of the memory circuit 400b and the outer edge shape of the memory circuit 400c may be the same. That is, the memory circuits 400a to 400c in each data holding circuit 360 may include a first type memory circuit including the memory circuit 400a and second type memory circuits including the memory circuits 400b and 400c.

For example, the length of the outer edge shape of the first type memory circuit 400a in the column direction is different from the length of the outer edge shape of each of the second type memory circuits 400b and 400c in the column direction. More specifically, the length of the outer edge shape of the first type memory circuit 400a in the column direction is larger than the length of the outer edge shape of each of the second type memory circuits 400b and 400c in the column direction. In addition, the aspect ratio obtained by dividing the length in the column direction by the length in the row direction, of the outer edge shape of the first type memory circuit 400a, is different from the aspect ratio obtained by dividing the length in the column direction by the length in the row direction, of the outer edge shape of each of the second type memory circuits 400b and 400c. More specifically, the aspect ratio obtained by dividing the length in the column direction by the length in the row direction, of the outer edge shape of the first type memory circuit 400a, is higher than the aspect ratio obtained by dividing the length in the column direction by the length in the row direction, of the outer edge shape of each of the second type memory circuits 400b and 400c is arranged. In this case, as shown in FIG. 9, the length of the outer edge shape of the first type memory circuit 400a in the row direction may be smaller than the length of the outer edge shape of each of the second type memory circuits 400b and 400c in the row direction. On the other hand, the memory circuit 400b and the memory circuit 400c may have the same length in the column direction, the same length in the row direction, or the same aspect ratio obtained by dividing the length in the column direction by the length in the row direction.

By employing the arrangement as shown in FIG. 9, it is possible to arrange the memory circuits 400a to 400c in the data holding circuit 360 in accordance with the available space, rather than forming the data holding circuit 360 from only the memory circuits 400 having the same outer edge shape. Accordingly, the arrangement density of the memory circuits 400a to 400c in the data holding circuit 360 can be improved. When the arrangement density of the memory circuits 400a to 400c is improved, the length of the light emitting device 100 in the column direction can be reduced, so that the size of the light emitting device 100 can be reduced. As a result, more light emitting devices 100 can be obtained from one substrate, and an effect of suppressing the manufacturing cost of the light emitting device 100 can be obtained.

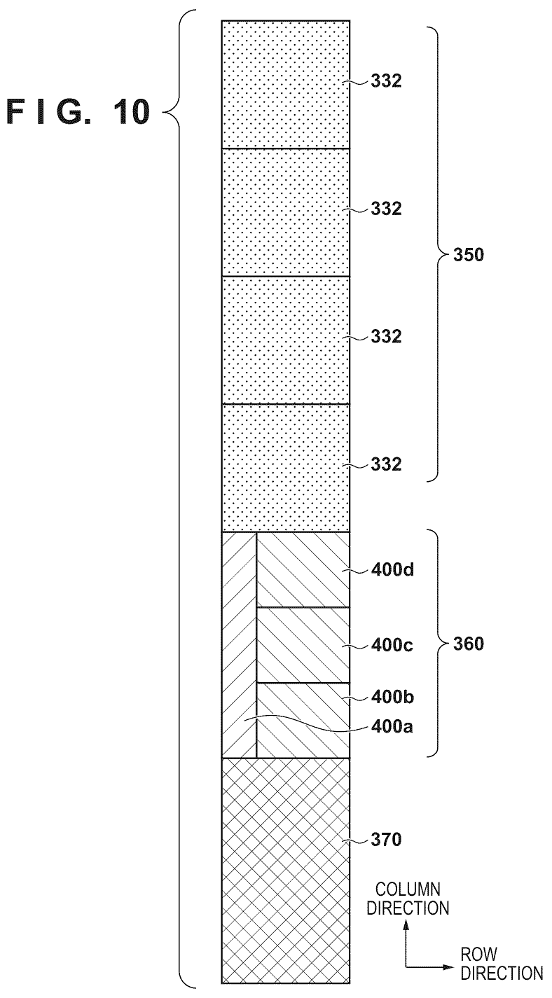

FIG. 10 shows an example of the arrangement of the column driving circuit 350, the data holding circuit 360, and the column selection circuit 370, in which four rows of the pixels PIX are arranged in one column. Four driving circuits 332 corresponding to the number of the pixels PIX arranged in one column are arranged in the column driving circuit 350. In the data holding circuit 360, four memory circuits 400a to 400d are arranged to hold data for controlling the four driving circuits 332.

In the arrangement shown in FIG. 10, the memory circuits 400b, 400c, and 400d are arranged to align in the column direction. The memory circuits 400a and 400b are arranged to align in the row direction, the memory circuits 400a and 400c are arranged to align in the row direction, and the memory circuits 400a and 400d are arranged to align in the row direction. The memory circuit 400a can be the first type memory circuit described above, and the memory circuits 400b to 400d can be the second type memory circuits described above. That is, the outer edge shape of the memory circuit 400a is different from the outer edge shapes of the memory circuits 400b to 400d. On the other hand, the memory circuits 400b to 400d may have the same outer edge shape.

Similar to the arrangement shown in FIG. 9, the memory circuits 400a to 400d having different outer edge shapes are used. With this, as compared to a case of forming the data holding circuit 360 from only the memory circuits 400 having the same outer edge shape, it is possible to improve the arrangement density and arrange the data holding circuit 360 with a smaller area. As described above, in each of the columns in which the pixels PIX are arranged, the driving circuits 332 arranged in the pixels PIX in the corresponding column are arranged to align in the column direction. In this case, as shown in FIGS. 9 and 10, the length in the column direction where the driving circuits 332 are arranged may be larger than the length in the column direction where the memory circuits 400 are arranged. In other words, the length occupied by the memory circuits 400 in the column direction may be smaller than the length occupied by the driving circuits 332 in the column direction.

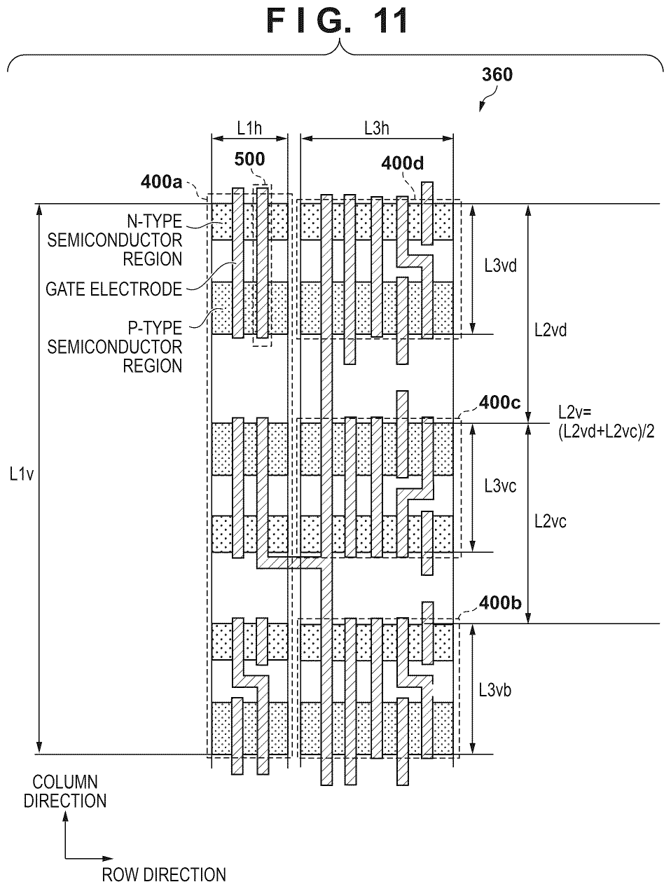

FIG. 11 is a view showing an example of the arrangement of the four memory circuits 400a to 400d included in the data holding circuit 360 shown in FIG. 10. The latch circuit shown in FIG. 6 is arranged as each of the memory circuits 400a to 400d, and each of the memory circuits 400a to 400d is configured to use five NMOS transistors and five PMOS transistors. In this embodiment, the NMOS transistor is formed by including a region where an n-type semiconductor region and the gate electrode overlap, and the PMOS transistor is formed by including a region where a p-type semiconductor region and the gate electrode overlap. The arrangement shown in FIG. 11 shows an example in which the gate electrodes of the respective transistors are arranged along the column direction. It can also be said that transistors constituting each of the memory circuits 400a to 400d in each data holding circuit 360 are arranged to cause a current to flow in the row direction in a channel region. In this case, as shown in FIG. 11, all transistors constituting each of the memory circuits 400a to 400d may be arranged to cause a current to flow in the row direction in the channel region. This can reduce the length of each of the memory circuits 400a to 400d in the row direction.

In the arrangement shown in FIG. 11, all transistors in the memory circuits 400b to 400d are used as elements constituting the memory circuits. On the other hand, in the memory circuit 400a, one NMOS transistor and one PMOS transistor are arranged as a redundant element 500. As can be understood from the difference in the outer edge shape described above, the circuit layout of the first type memory circuit 400a may be different from the circuit layout of each of the second type memory circuits 400b to 400d. In this embodiment, the circuit layout refers to the positional relationship among the elements arranged in the circuit.

In this embodiment, the outer edge shape of the memory circuit 400 described above can be a shape formed by connecting the outermost region of the n-type semiconductor region and the outermost region of the p-type semiconductor region, which constitute the memory circuit 400. For example, the length of the outer edge shape of the first type memory circuit 400a in the row direction is L1h, and the length of the outer edge shape thereof in the column direction is L1v. For example, the length of the outer edge shape of the second type memory circuit 400d in the row direction is L3h, and the length of the outer edge shape thereof in the column direction is L3vd.

As described above, the length L1h in the row direction where the transistors constituting the first type memory circuit 400a are arranged is smaller than the length L3h in the row direction where the transistors constituting the second type memory circuits 400b to 400d are arranged. The length L1v in the column direction where the transistors constituting the first type memory circuit 400a are arranged is larger than each of lengths L3vb to L3vd in the column direction where the transistors constituting each of the second type memory circuits 400b to 400d are arranged. As shown in FIG. 11, the lengths of the outer edge shape of the memory circuits 400b to 400d in the row direction, respectively, can all be the length L3h. The lengths L3vb to L3vd of the outer edge shape of the memory circuits 400b to 400d in the column direction, respectively, may be the same. However, the present disclosure is not limited to this, and the length of the outer edge shape of each of the memory circuits 400b to 400d in the row direction and the length of the outer edge shape of each of the memory circuits 400b to 400d in the column direction may be different among the memory circuits 400b to 400d.

Here, the interval for the second type memory circuits 400b to 400d aligned in the column direction is defined. The arrangement interval between the memory circuit 400d and the memory circuit 400c in the column direction is indicated by a length L2vd, and the arrangement interval between the memory circuit 400c and the memory circuit 400b in the column direction is indicated by a length L2vc. In this case, the interval for the second type memory circuits 400b to 400d arranged in the column direction is defined as a length L2v, which is the average value of the length L2vd and the length L2vc. The length L2vd and the length L2vc may be the same.

In the data holding circuit 360, the first type memory circuit 400a and each of a predetermined number (two in the arrangement shown in FIG. 9, three in the arrangement shown in FIGS. 10 and 11, and a description will be given assuming that the predetermined number is three as in the arrangement shown in FIG. 11) of the second type memory circuits 400b to 400d are arranged to align in the row direction, and the three second type memory circuits 400b to 400d are arranged to align in the column direction. In this case, a relationship expressed by

$$L 2 vd , L 2 vc < L 1 v < 3 \times L 2 vd , 3 \times L 2 vc$$

may be satisfied.

In this embodiment, the aspect ratio obtained by dividing the length L1v in the column direction by the length L1h in the row direction, of the outer edge shape of the first type memory circuit 400a, is higher than the aspect ratio obtained by dividing each of the lengths L3vb to L3vd in the column direction by the length L3h in the row direction, of the outer edge shape of the second type memory circuits 400b to 400d. The memory circuits 400b to 400d each having the low aspect ratio are arranged to align in the column direction, and the memory circuits 400b to 400d and the memory circuit 400a having the high aspect ratio are arranged to align in the row direction. In the data holding circuit 360 arranged corresponding to each pixel column, the number of the first type memory circuits 400a having the high aspect ratio is smaller than the number of the second type memory circuits 400b to 400d. By increasing the number of the memory circuits 400b to 400d each having the low aspect ratio and aligned in the column direction, the length of the data holding circuit 360 in the column direction can be reduced.

The N memory circuits 400 for driving the pixels PIX in N rows and one column include S first type memory circuits 400a having the high aspect ratio and (N−S) second type memory circuits 400b to 400d each having the low aspect ratio. In this case, S<(N−S) can be satisfied. Also, the length L1v of the outer edge shape of the first type memory circuit 400a having the high aspect ratio in the column direction is larger than the interval L2v for the second type memory circuits 400b to 400d each having the low aspect ratio and aligned in the column direction, and is smaller than the value obtained by multiplying the interval L2v by (N−S). This relationship in the column direction defines a constraint on the length L1v of the outer edge shape of the first type memory circuit 400a having the high aspect ratio in the column direction. This also defines a relationship that can suppress the length in the column direction by combining the memory circuits 400 having different aspect ratios rather than arranging N second type memory circuits 400 each having the low aspect ratio.

In this manner, the arrangement according to this embodiment can improve the arrangement density of the memory circuits 400 in the data holding circuit 360. This can reduce the length of the light emitting device 100 in the column direction, thereby reducing the size of the light emitting device 100. As a result, more light emitting devices 100 can be obtained from one substrate, and an effect of suppressing the manufacturing cost of the light emitting device 100 can be obtained.

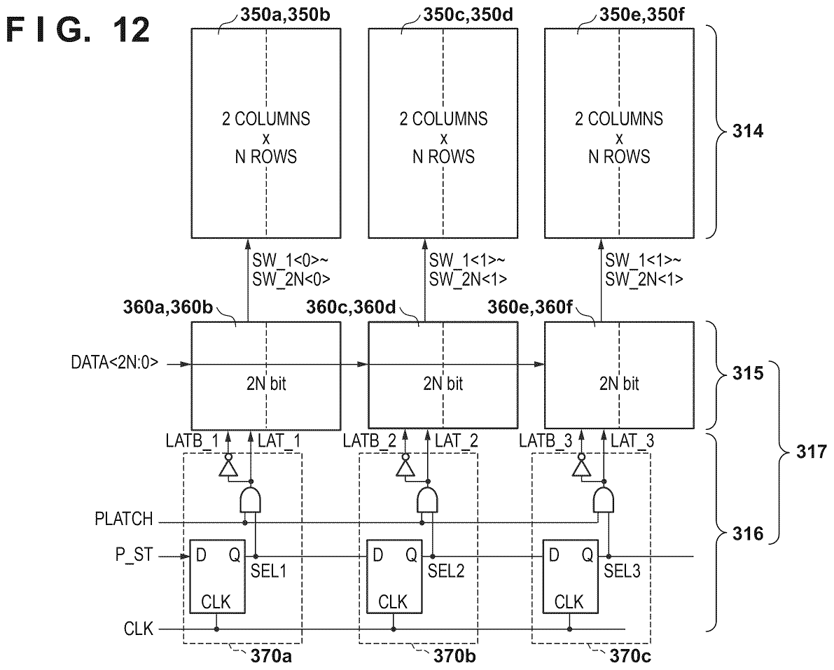

FIG. 12 shows a modification of the arrangement shown in FIG. 4. More specifically, FIG. 12 shows an example of the arrangement of the pixel driving unit 314 corresponding to the light emitting elements O in N rows and six columns, and the column selection unit 316 and the data holding unit 315 constituting the scanning circuit 317. The arrangement shown in FIG. 12 is different from the arrangement shown in FIG. 4 in the arrangement of the column selection unit 316 of the scanning circuit 317. The arrangement except for the column selection unit 316 may be similar to the embodiment described above, so that differences will mainly be described, and a description of similar points will be omitted as appropriate.

In the arrangement shown in FIG. 4, each of the column selection circuits 370a to 370c arranged in the column selection unit 316 of the scanning circuit 317 is arranged corresponding to each column in which the pixels PIX are arranged. On the other hand, in the arrangement shown in FIG. 12, each of the column selection circuits 370a to 370c is arranged so as to simultaneously select at least two data holding circuits out of the data holding circuits 360. For example, the column selection circuit 370a is arranged so as to simultaneously select two data holding circuits 360a and 360b provided corresponding to adjacent columns among the columns. The same applies to the column selection circuits 370b and 370c.

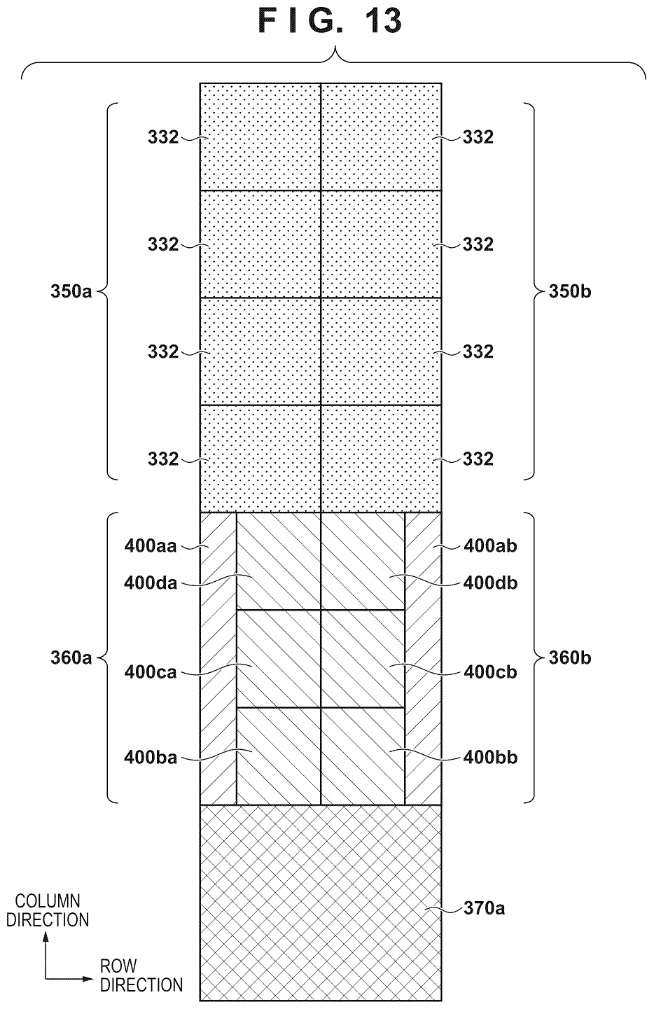

FIG. 13 shows an example of the arrangement of the column driving circuits 350a and 350b, the data hold circuits 360a and 360b, and the column selection circuit 370a shown in FIG. 12. Similar to FIG. 10, this is an example of the arrangement in which four rows of the pixels PIX are arranged in one column. In the arrangement shown in FIG. 13, one column selection circuit 370a can be arranged across the row-direction widths of the column driving circuits 350a and 350b in two columns. Accordingly, the column selection circuit 370a can be made smaller in the column direction. That is, it is possible to reduce the length of the light emitting device 100 in the column direction, thereby reducing the size of the light emitting device 100. As a result, more light emitting devices 100 can be obtained from one substrate, and an effect of suppressing the manufacturing cost of the light emitting device 100 can be obtained.

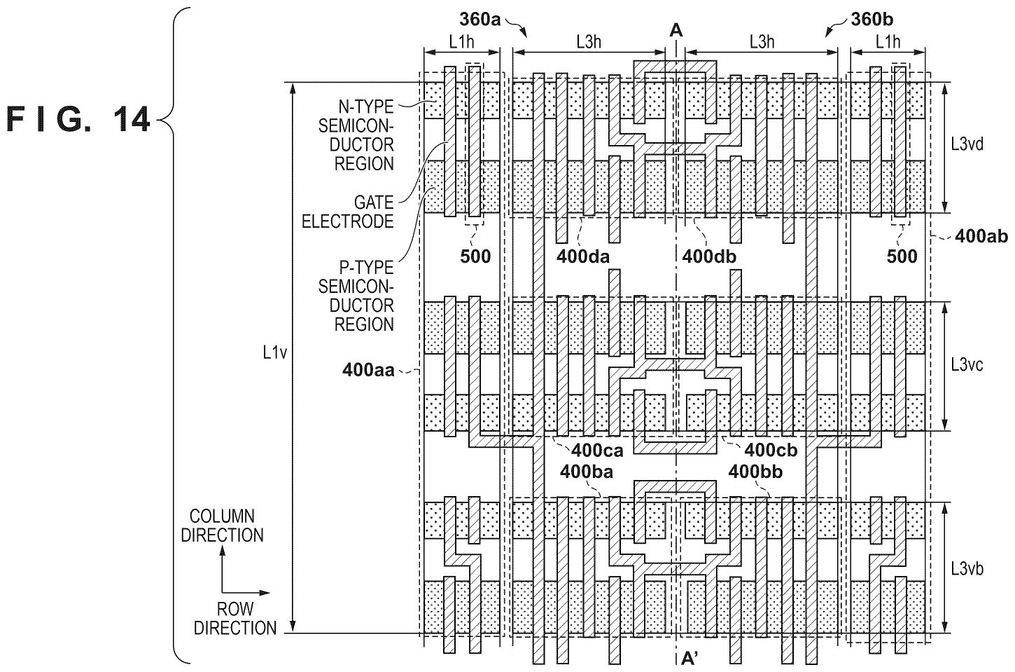

FIG. 14 is a view showing an example of the arrangement of four memory circuits 400aa to 400da included in the data holding circuit 360a and four memory circuits 400ab to 400db included in the data holding circuit 360b shown in FIG. 13. Similar to the arrangement shown in FIG. 11, the latch circuit shown in FIG. 6 is arranged as each of the memory circuits 400aa to 400db, and each of the memory circuits 400aa to 400db is configured to use five NMOS transistors and five PMOS transistors. In this embodiment, the NMOS transistor is formed by including a region where an n-type semiconductor region and the gate electrode overlap, and the PMOS transistor is formed by including a region where a p-type semiconductor region and the gate electrode overlap. The arrangement shown in FIG. 14 shows an example in which the gate electrodes of the respective transistors are arranged along the column direction. It can also be said that transistors constituting each of the memory circuits 400aa to 400db in each data holding circuit 360 are arranged to cause a current to flow in the row direction in a channel region. As shown in FIG. 14, all transistors constituting each of the memory circuits 400aa to 400db may be arranged to cause a current to flow in the row direction in the channel region.

In the arrangement shown in FIG. 14, all transistors in the memory circuits 400ba to 400da and 400bb to 400db are used as elements constituting the memory circuits. On the other hand, in each of the memory circuits 400aa and 400ab, one NMOS transistor and one PMOS transistor are arranged as the redundant element 500.

As shown in FIG. 14, in a planar view, the elements (transistors) arranged in the memory circuits 400aa to 400da in the data holding circuit 360a and the elements (transistors) arranged in the memory circuits 400ab to 400db in the data holding circuit 360b may be arranged at line-symmetric positions with respect to a virtual line A-A′ passing through the boundary between the data holding circuit 360a and the data holding circuit 360b. The line-symmetric arrangement allows the memory circuits to share a control line between the memory circuits 400ba and 400bb, between the memory circuits 400da and 400db, and between the memory circuits 400ca and 400cb. Therefore, the number of control lines can be decreased, and the size of the data holding unit 315 can be reduced.

In this manner, the arrangement according to each embodiment described above enables miniaturization of the light emitting device 100. This increases the number of the light emitting devices 100 that can be obtained from one substrate, making it possible to manufacture the light emitting device 100 at low cost.

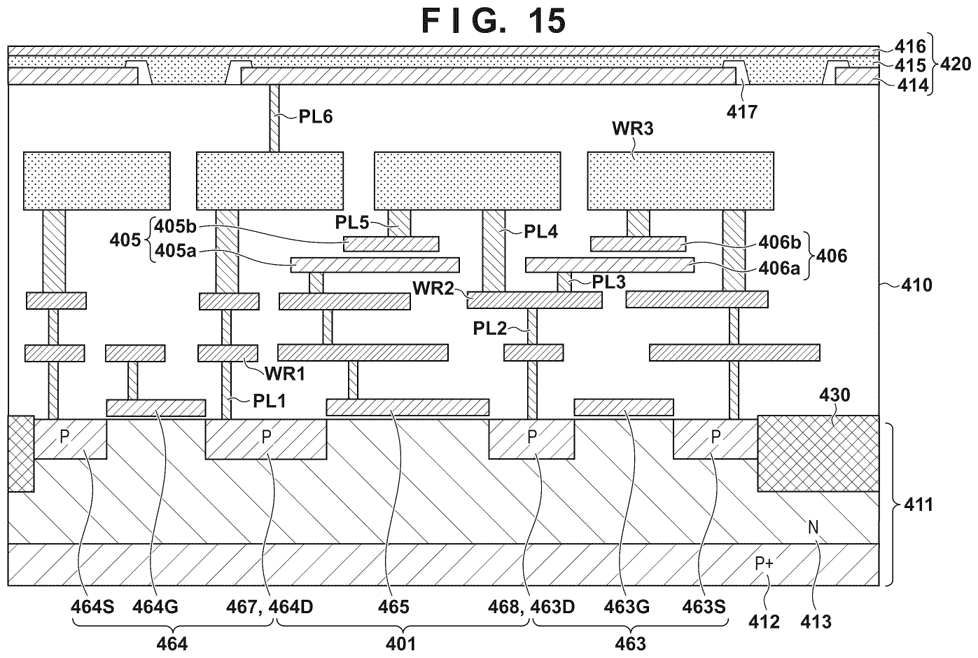

Here, application examples in which the light emitting device 100 according to this embodiment is applied to an image forming apparatus, a display apparatus, a photoelectric conversion apparatus, electronic equipment, an illumination apparatus, a moving body, and a wearable device will be described with reference to FIGS. 15 to 24B. The description will be given assuming that, for example, the above-described light emitting element O such as an organic EL element (OLED) using an organic light emitting material is arranged in the pixel arranged in the light emitting device 100. Details of each component arranged in the pixel PIX of the light emitting device 100 described above will be described first, and the application examples will be described after that.

The organic light emitting element according to this embodiment includes a first electrode, a second electrode, and an organic compound layer arranged between these electrodes. One of the first electrode and the second electrode is an anode, and the other is a cathode. In the organic light emitting element according to this embodiment, the organic compound layer may be either a single layer or a stacked body formed by layers as long as it includes a light emitting layer. Here, if the organic compound layer is a stacked body formed from layers, the organic compound layer may include a hole injection layer, a hole transport layer, an electron blocking layer, a hole/exciton blocking layer, an electron transport layer, an electron injection layer, and the like in addition to the light emitting layer. The light emitting layer may be a single layer or a stacked body formed from layers. If the light emitting layer includes layers, a charge generation layer may be arranged between the light emitting layers. The charge generation layer may be made of a compound having the LUMO lower than that of the hole transport layer, and the LUMO of the charge generation layer may be lower than the HOMO of the hole transport layer. Here, the molecular orbital energy of the organic compound layer may be the molecular orbital energy of the organic compound with the largest weight ratio in the organic compound layer.

In the organic light emitting element according to this embodiment, if an organic compound is contained in the light emitting layer, the light emitting layer may be a layer made of only the organic compound or a layer made of the organic metal complex and another compound. Here, if the light emitting layer is a layer made of the organic metal complex and another compound, the organic compound may be used as a host or a guest of the light emitting layer. Alternatively, the organic compound may be used as an assist material that can be contained in the light emitting layer. Here, the host is a compound whose mass ratio is largest in the compounds forming the light emitting layer. The guest is a compound whose mass ratio is smaller than that of the host in the compounds forming the light emitting layer, and is a compound responsible for main light emission. The assist material is a compound whose mass ratio is smaller than that of the host in the compounds forming the light emitting layer, and which assists light emission of the guest. The assist material can also be called a second host. The host material can be called a first compound, and the assist material as a second compound.

Here, for the organic compound, a conventionally known low molecular and high molecular hole injection compound or hole transport compound, a compound serving as a host, a light emitting compound, an electron injection compound or electron transport compound, or the like can be used together as needed.

As a hole injection/transport material, a material that has a high hole mobility such that hole injection from the anode is facilitated, and injected holes can be transported to the light emitting layer can suitably be used. Also, a material having a high glass transition point temperature can suitably be used to reduce degradation of film quality such as crystallization in the organic light emitting element.

The electron transport material can arbitrarily be selected from materials capable of transporting electrons injected from the cathode to the light emitting layer, and is selected in consideration of balance to the hole mobility of the hole transport material. The electron transport material can also be used for the hole blocking layer.

The electron injection material can arbitrarily be selected from materials capable of facilitating electron injection from the cathode, and is selected in consideration of balance to hole injection. The electron injection material can also be used together with the electron transport material.

### Configuration of Organic Light Emitting Element

The organic light emitting element is provided by forming an insulating layer, a first electrode, an organic compound layer, and a second electrode on a substrate. A protection layer, a color filter, a microlens, and the like may be provided on a cathode. If a color filter is provided, a planarizing layer may be provided between the protection layer and the color filter. The planarizing layer can be formed using acrylic resin or the like. The same applies to a case where a planarizing layer is provided between the color filter and the microlens.

### Substrate

Quartz, glass, a silicon wafer, a resin, a metal, or the like may be used as a substrate. Furthermore, a switching element such as a transistor, a wiring pattern, and the like may be provided on the substrate, and an insulating layer may be provided thereon. When using a silicon wafer as the substrate, the active layer, source region, and drain region of a transistor are formed in the substrate. This is suitable since dense arrangement of the transistors is possible. The insulating layer may be made of any material as long as a contact hole can be formed so that the wiring pattern can be formed between the first electrode and the substrate and insulation from the unconnected wiring pattern can be ensured. For example, a resin such as polyimide, silicon oxide, silicon nitride, or the like may be used for the insulating layer.

### Electrode

A pair of electrodes can be used as the electrodes. The pair of electrodes can be an anode and a cathode. If an electric field is applied in the direction in which the organic light emitting element emits light, the electrode having a high potential is the anode, and the other is the cathode. It can also be said that the electrode that supplies holes to the light emitting layer is the anode and the electrode that supplies electrons is the cathode.

As the constituent material of the anode, a material having a large work function may be selected. For example, a metal such as gold, platinum, silver, copper, nickel, palladium, cobalt, selenium, vanadium, or tungsten, a mixture containing some of them, an alloy obtained by combining some of them, or a metal oxide such as tin oxide, zinc oxide, indium oxide, indium tin oxide (ITO), or zinc indium oxide can be used. Furthermore, a conductive polymer such as polyaniline, polypyrrole, or polythiophene can also be used as the constituent material of the anode.

One of these electrode materials may be used singly, or two or more of them may be used in combination. The anode may be formed by a single layer or multiple layers.

If the electrode is used as a reflective electrode, for example, chromium, aluminum, silver, titanium, tungsten, molybdenum, an alloy thereof, a stacked layer thereof, or the like can be used. The above materials can function as a reflective film having no role as an electrode. If a transparent electrode is used as the electrode, an oxide transparent conductive layer made of indium tin oxide (ITO), indium zinc oxide, or the like can be used, but the present disclosure is not limited thereto. A photolithography technique can be used to form the electrode.

On the other hand, as the constituent material of the cathode, a material having a small work function may be selected. Examples of the material include an alkali metal such as lithium, an alkaline earth metal such as calcium, a metal such as aluminum, titanium, manganese, silver, lead, or chromium, and a mixture containing some of them. Alternatively, an alloy obtained by combining these metals can also be used. For example, a magnesium-silver alloy, an aluminum-lithium alloy, an aluminum-magnesium alloy, a silver-copper alloy, a zinc-silver alloy, or the like can be used. A metal oxide such as indium tin oxide (ITO) can also be used. One of these electrode materials may be used singly, or two or more of them may be used in combination. The cathode may have a single-layer structure or a multilayer structure. Silver may be used as the cathode. To suppress aggregation of silver, a silver alloy may be used. The ratio of the alloy is not limited as long as aggregation of silver can be suppressed. For example, the ratio between silver and another metal may be 1:1, 3:1, or the like.

The cathode may be a top emission element using an oxide conductive layer made of ITO or the like, or may be a bottom emission element using a reflective electrode made of aluminum (Al) or the like, and is not particularly limited. The method of forming the cathode is not particularly limited, but if direct current sputtering or alternating current sputtering is used, the good coverage is achieved for the film to be formed, and the resistance of the cathode can be lowered.

### Pixel Isolation Layer

A pixel isolation layer may be formed by a so-called silicon oxide, such as silicon nitride (SiN), silicon oxynitride (SiON), or silicon oxide (SiO), formed using a Chemical Vapor Deposition (CVD) method. To increase the resistance in the in-plane direction of the organic compound layer, the organic compound layer, especially the hole transport layer may be thinly deposited on the side wall of the pixel isolation layer. More specifically, the organic compound layer can be deposited so as to have a thin film thickness on the side wall by increasing the taper angle of the side wall of the pixel isolation layer or the film thickness of the pixel isolation layer to increase vignetting during vapor deposition.

On the other hand, the taper angle of the side wall of the pixel isolation layer or the film thickness of the pixel isolation layer can be adjusted to the extent that no space is formed in the protection layer formed on the pixel isolation layer. Since no space is formed in the protection layer, it is possible to reduce generation of defects in the protection layer. Since generation of defects in the protection layer is reduced, a decrease in reliability caused by generation of a dark spot or occurrence of a conductive failure of the second electrode can be reduced.

According to this embodiment, even if the taper angle of the side wall of the pixel isolation layer is not acute, it is possible to effectively suppress leakage of charges to an adjacent pixel. As a result of this consideration, it has been found that the taper angle of 60° (inclusive) to 90° (inclusive) can sufficiently reduce the occurrence of defects. The film thickness of the pixel isolation layer may be 10 nm (inclusive) to 150 nm (inclusive). A similar effect can be obtained in a configuration including only pixel electrodes without the pixel isolation layer. However, in this case, the film thickness of the pixel electrode is set to be equal to or smaller than half the film thickness of the organic layer or the end portion of the pixel electrode is formed to have a forward tapered shape of less than 60°. With this, short circuit of the organic light emitting element can be reduced.

Furthermore, in a case where the first electrode is the cathode and the second electrode is the anode, a high color gamut and low-voltage driving can be achieved by forming the electron transport material and charge transport layer and forming the light emitting layer on the charge transport layer.

### Organic Compound Layer

The organic compound layer may be formed by a single layer or multiple layers. If the organic compound layer includes layers, the layers can be called a hole injection layer, a hole transport layer, an electron blocking layer, a light emitting layer, a hole blocking layer, an electron transport layer, and an electron injection layer in accordance with the functions of the layers. The organic compound layer is mainly formed from an organic compound but may contain inorganic atoms and an inorganic compound. For example, the organic compound layer may contain copper, lithium, magnesium, aluminum, iridium, platinum, molybdenum, zinc, or the like. The organic compound layer may be arranged between the first and second electrodes, and may be arranged in contact with the first and second electrodes.

If light emitting layers are provided, a charge generation portion may be arranged between the first light emitting layer and the second light emitting layer which are stacked. The charge generation portion may contain an organic compound with a lowest unoccupied molecular orbital energy (LUMO) of −5.0 eV or less. The same applies to a case where a charge generating portion is provided between the second light emitting layer and the third light emitting layer which are stacked.

### Protection Layer

A protection layer may be provided on the cathode. For example, by adhering glass provided with a moisture absorbing agent on the cathode, permeation of water or the like into the organic compound layer can be suppressed and occurrence of display defects can be suppressed. Furthermore, as another embodiment, a passivation layer made of silicon nitride or the like may be provided on the cathode to suppress permeation of water or the like into the organic compound layer. For example, the protection layer can be formed by forming the cathode, transferring it to another chamber without breaking the vacuum, and forming silicon nitride having a thickness of 2 μm by the CVD method. The protection layer may be provided using an atomic layer deposition (ALD) method after deposition of the protection layer using the CVD method. The material of the protection layer by the ALD method is not limited but can be silicon nitride, silicon oxide, aluminum oxide, or the like. Silicon nitride may further be formed by the CVD method on the protection layer formed by the ALD method. The protection layer formed by the ALD method may have a film thickness smaller than that of the protection layer formed by the CVD method. More specifically, the film thickness of the protection layer formed by the ALD method may be 50% or less, or 10% or less of that of the protection layer formed by the CVD method.

### Color Filter

A color filter may be provided on the protection layer. For example, a color filter considering the size of the organic light emitting element may be provided on another substrate, and the substrate with the color filter formed thereon may be bonded to the substrate with the organic light emitting element provided thereon. Alternatively, for example, a color filter may be patterned on the above-described protection layer using a photolithography technique. The color filter may be formed from a polymeric material.

### Planarizing Layer

A planarizing layer may be arranged between the color filter and the protection layer. The planarizing layer is provided to reduce unevenness of the layer below the planarizing layer. The planarizing layer may be called a material resin layer without limiting the purpose of the layer. The planarizing layer may be formed from an organic compound, and may be made of a low-molecular material or a polymeric material. In consideration of reduction of unevenness, a polymeric organic compound may be used for the planarizing layer.

The planarizing layers may be provided above and below the color filter. In that case, the same or different constituent materials may be used for these planarizing layers. More specifically, examples of the material of the planarizing layer include polyvinyl carbazole resin, polycarbonate resin, polyester resin, ABS resin, acrylic resin, polyimide resin, phenol resin, epoxy resin, silicone resin, and urea resin.

### Microlens

The organic light emitting device may include an optical member such as a microlens on the light emission side. The microlens can be made of acrylic resin, epoxy resin, or the like. The microlens can aim to increase the amount of light extracted from the organic light emitting device and control the direction of light to be extracted. The microlens can have a hemispherical shape. If the microlens has a hemispherical shape, among tangents contacting the hemisphere, there is a tangent parallel to the insulating layer, and the contact between the tangent and the hemisphere is the vertex of the microlens. The vertex of the microlens can be decided in the same manner even in an arbitrary sectional view. That is, among tangents contacting the semicircle of the microlens in a sectional view, there is a tangent parallel to the insulating layer, and the contact between the tangent and the semicircle is the vertex of the microlens.

Furthermore, the middle point of the microlens can also be defined. In the section of the microlens, a line segment from a point at which an arc shape ends to a point at which another arc shape ends is assumed, and the middle point of the line segment can be called the middle point of the microlens. A section for determining the vertex and the middle point may be a section perpendicular to the insulating layer.

The microlens includes a first surface including a convex portion and a second surface opposite to the first surface. The second surface can be arranged on the functional layer (light emitting layer) side of the first surface. For this configuration, the microlens needs to be formed on the light emitting device. If the functional layer is an organic layer, a process which produces high temperature in the manufacturing step of the microlens may be avoided. In addition, if it is configured to arrange the second surface on the functional layer side of the first surface, all the glass transition temperatures of an organic compound forming the organic layer may be 100° C. or more. For example, 130° C. or more is suitable.

### Counter Substrate

A counter substrate may be arranged on the planarizing layer. The counter substrate is called a counter substrate because it is provided at a position corresponding to the above-described substrate. The constituent material of the counter substrate can be the same as that of the above-described substrate. If the above-described substrate is the first substrate, the counter substrate can be the second substrate.

### Organic Layer

The organic compound layer (hole injection layer, hole transport layer, electron blocking layer, light emitting layer, hole blocking layer, electron transport layer, electron injection layer, and the like) forming the organic light emitting element according to an embodiment of the present disclosure may be formed by the method to be described below.

The organic compound layer forming the organic light emitting element according to the embodiment of the present disclosure can be formed by a dry process using a vacuum deposition method, an ionization deposition method, a sputtering method, a plasma method, or the like. Instead of the dry process, a wet process that forms a layer by dissolving a solute in an appropriate solvent and using a well-known coating method (for example, a spin coating method, a dipping method, a casting method, an LB method, an inkjet method, or the like) can be used.

Here, when the layer is formed by a vacuum deposition method, a solution coating method, or the like, crystallization or the like hardly occurs and excellent temporal stability is obtained. Furthermore, when the layer is formed using a coating method, it is possible to form the film in combination with a suitable binder resin.

Examples of the binder resin include polyvinyl carbazole resin, polycarbonate resin, polyester resin, ABS resin, acrylic resin, polyimide resin, phenol resin, epoxy resin, silicone resin, and urea resin. However, the binder resin is not limited to them.

One of these binder resins may be used singly as a homopolymer or a copolymer, or two or more of them may be used in combination. Furthermore, additives such as a well-known plasticizer, antioxidant, and an ultraviolet absorber may also be used as needed.

### Pixel Circuit

The light emitting device can include a pixel circuit connected to the light emitting element. The pixel circuit may be an active matrix circuit that individually controls light emission of the first and second light emitting elements. The active matrix circuit may be a voltage or current programing circuit. A driving circuit includes a pixel circuit for each pixel. The pixel circuit can include a light emitting element, a transistor for controlling light emission luminance of the light emitting element, a transistor for controlling a light emission timing, a capacitor for holding the gate voltage of the transistor for controlling the light emission luminance, and a transistor for connection to GND without intervention of the light emitting element.

The light emitting device includes a display region and a peripheral region arranged around the display region. The light emitting device includes the pixel circuit in the display region and a display control circuit in the peripheral region. The mobility of the transistor forming the pixel circuit may be smaller than that of a transistor forming the display control circuit.

The slope of the current-voltage characteristic of the transistor forming the pixel circuit may be smaller than that of the current-voltage characteristic of the transistor forming the display control circuit. The slope of the current-voltage characteristic can be measured by a so-called Vg-Ig characteristic.

The transistor forming the pixel circuit is a transistor connected to the light emitting element such as the first light emitting element.

### Pixel

The organic light emitting device includes pixels. Each pixel includes sub-pixels that emit light components of different colors. The sub-pixels may include, for example, R, G, and B emission colors, respectively.

In each pixel, a region also called a pixel opening emits light. The pixel opening can have a size of 5 μm (inclusive) to 15 μm (inclusive). More specifically, the pixel opening can have a size of 11 μm, 9.5 μm, 7.4 μm, 6.4 μm, or the like.

A distance between the sub-pixels can be 10 μm or less, and can be, more specifically, 8 μm, 7.4 μm, or 6.4 μm.

The pixels can have a known arrangement form in a plan view. For example, the pixels may have a stripe arrangement, a delta arrangement, a pentile arrangement, or a Bayer arrangement. The shape of each sub-pixel in a plan view may be any known shape. For example, a quadrangle such as a rectangle or a rhombus, a hexagon, or the like may be possible. A shape which is not a correct shape but is close to a rectangle is included in a rectangle, as a matter of course. The shape of the sub-pixel and the pixel arrangement can be used in combination.

### Application of Organic Light Emitting Element of Embodiment of Present Disclosure

The organic light emitting element according to an embodiment of the present disclosure can be used as a constituent member of a display apparatus or an illumination apparatus. In addition, the organic light emitting element is applicable to the exposure light source of an electrophotographic image forming apparatus, the backlight of a liquid crystal display apparatus, a light emitting device including a color filter in a white light source, and the like.

The display apparatus may be an image information processing apparatus that includes an image input unit for inputting image information from an area CCD, a linear CCD, a memory card, or the like, and an information processing unit for processing the input information, and displays the input image on a display unit.

In addition, a display unit included in an image capturing apparatus or an inkjet printer can have a touch panel function. The driving type of the touch panel function may be an infrared type, a capacitance type, a resistive film type, or an electromagnetic induction type, and is not particularly limited. The display apparatus may be used for the display unit of a multifunction printer.

More details will be described next with reference to the accompanying drawing. FIG. 15 is a sectional view showing an example of the arrangement of a pixel of a light emitting device according to this embodiment. The light emitting device includes a substrate 411, an insulating layer 410, and a light emitting element 420. The insulating layer 410 is located on the substrate 411. The light emitting element 420 is located on the insulating layer 410. In other words, the insulating layer 410 is located between the substrate 411 and the light emitting element 420.

The substrate 411 includes a main surface (the upper surface in FIG. 15) in which a driving transistor 401, a write control transistor 464, and a light emission control transistor 463 are formed. The substrate 411 may be formed of, for example, a p-type semiconductor. An n-type well region 413 is formed on the main surface side of the substrate 411 (that is, the upper side of the substrate 411). The region of the substrate 411 except for the well region 413 is a p-type semiconductor region 412.

The substrate 411 includes, in the well region 413, impurity regions each functioning as the source region or drain region of a transistor. The conductivity type of all of the impurity regions can be, for example, a p type.

A conductive layer 465, a conductive layer 463G, and a conductive layer 464G are arranged on the main surface (upper surface) of the substrate 411. The conductive layer 463G functions as the gate of the light emission control transistor 463. One of the p-type impurity regions functions as a source 463S of the light emission control transistor 463, and another one of the p-type impurity regions functions as a drain 463D. The conductive layer 465 functions as the gate of the driving transistor 461. The impurity region functioning as the drain 463D of the light emission control transistor 463 also functions as a source 468 of the driving transistor 401. Still another one of the p-type impurity regions functions as a drain 467 of the driving transistor 401.

The conductive layer 464G functions as the gate of a reset transistor 464. The impurity region functioning as the source 468 of the driving transistor 401 also functions as a drain 464D of the reset transistor 464. Still another one of the p-type impurity regions functions as a source 464S of the reset transistor 464.

The substrate 411 further includes an element isolation portion 430 formed between adjacent pixels. As the element isolation portion 430, Shallow Trench Isolation (STI), LOCal Oxidation of Silicon (LOCOS) isolation, isolation by an n-type diffusion layer, or the like may be used.

The light emitting element 420 includes a cathode 416, an organic light emitting layer 415, and an anode 414. The cathode 416 is electrically connected to a power supply line 408. The anode 414 is electrically connected to the main terminal (drain here) of the driving transistor 401. The organic light emitting layer 415 is located between the cathode 416 and the anode 414. A bank portion 417 is arranged in the end portion of the anode 414. The bank portion 417 suppresses that a current flowing between the anode 414 and the cathode 416 leaks to an adjacent pixel 101.

Conductive patterns, electrodes of capacitive elements, plugs, and the like are embedded in the insulating layer 410. The insulating layer 410 may be formed by containing, for example, silicon oxide. Each conductive pattern may be a wiring layer. For example, as shown in FIG. 15, the conductive patterns may include a wiring pattern WR1, a wiring pattern WR2, and a wiring pattern WR3.

A capacitive element 405 includes an electrode 405a and an electrode 405b, and a capacitive element 406 includes an electrode 406a and an electrode 406b. In the insulating layer 410, the electrode 405a and the electrode 406a may be arranged on the same insulating layer. The electrode 405b and the electrode 406b may be arranged on the same insulating layer. The electrode 405a and the electrode 405b face each other with the insulating layer therebetween. The electrode 406a and the electrode 406b face each other with the insulating layer therebetween. Thus, the capacitive elements each having a Metal-Insulator-Metal (MIM) structure are formed.

The plugs may include, for example, a plug PL1, a plug PL2, a plug PL3, a plug PL4, and a plug PL5. All the plugs may have the same thickness or different thicknesses. They may have the same thickness in one part and different thicknesses in the other part.

The plug PL1 may connect the wiring pattern WR1 and the terminal (one of the gate, source, and drain) of the transistor. The plug PL2 may connect the wiring pattern WR1 and the wiring pattern WR2. The lower electrode of the capacitive element (405 or 406) may be connected to the driving transistor 401 via the plug PL3, the wiring pattern WR2, the plug PL2, the wiring pattern WR1, and the plug PL1. The upper electrode of the capacitive element (405 or 406) may be connected to the wiring pattern WR3 via the plug PL5.

The wiring pattern WR3 may be connected to the transistor (in FIG. 15, one of the driving transistor, the light emission control transistor, and the reset transistor) via the plug PL4, the wiring pattern WR2, the plug PL2, the wiring pattern WR1, and the plug PL1. The anode 414 may be connected to the drain 467 of the driving transistor 401 via the plug PL6, the wiring pattern WR3, the plug PL4, the wiring pattern WR2, the plug PL2, the wiring pattern WR1, and the plug PL1.

The plug may be formed in a step different from a step for the wiring pattern, or may be formed in the same step as the wiring pattern arranged on the plug. For example, the wiring pattern WR2 and the plug PL2 may be formed in the same step and contain the same material. The wiring pattern WR3 and the plug PL4 may be formed in the same step and contain the same material. The wiring pattern and plug can be formed using a metal such as copper, tungsten, aluminum, or titanium, or an alloy thereof.

In this manner, when a semiconductor substrate is used for the substrate, and the transistor of each pixel is formed as a MOS transistor, a further dense arrangement of the transistors is possible as compared to a case of using a thin film transistor as the transistor. Therefore, when the light emitting device according to this embodiment incudes a semiconductor substrate and MOS transistors as transistors, the light emitting device can have higher resolution or a smaller size.

FIG. 16A shows an example of the pixel arranged in the light emitting device 100. The pixel includes sub-pixels 810 (corresponding to the pixels PIX described above). The sub-pixels are divided into sub-pixels 810R, 810G, and 810B by emitted light components. The light emission colors may be discriminated by the wavelengths of light components emitted from the light emitting layers, or light emitted from each sub-pixel may be selectively transmitted or undergo color conversion by a color filter or the like. Each sub-pixel includes a reflective electrode 802 as the first electrode on an interlayer insulating layer 801, an insulating layer 803 covering the end of the reflective electrode 802, an organic compound layer 804 covering the first electrode and the insulating layer, a transparent electrode 805 as the second electrode, a protection layer 806, and a color filter 807.

The interlayer insulating layer 801 can include a transistor and a capacitive element arranged in the interlayer insulating layer 801 or a layer below it. The transistor and the first electrode can electrically be connected via a contact hole (not shown) or the like.

The insulating layer 803 can also be called a bank or a pixel isolation film. The insulating layer 803 covers the end of the first electrode, and is arranged to surround the first electrode. A portion of the first electrode where no insulating layer 803 is arranged is in contact with the organic compound layer 804 to form a light emitting region.

The organic compound layer 804 includes a hole injection layer 841, a hole transport layer 842, a first light emitting layer 843, a second light emitting layer 844, and an electron transport layer 845.

The second electrode may be a transparent electrode, a reflective electrode, or a semi-transmissive electrode.

The protection layer 806 suppresses permeation of water into the organic compound layer. The protection layer is shown as a single layer but may include layers. Each layer can be an inorganic compound layer or an organic compound layer.

The color filter 807 is divided into color filters 807R, 807G, and 807B by colors. The color filters can be formed on a planarizing film (not shown). A resin protection layer (not shown) may be arranged on the color filters. The color filters can be formed on the protection layer 806. Alternatively, the color filters can be provided on the counter substrate such as a glass substrate, and then the substrate may be bonded.

The display apparatus 800 (corresponding to the light emitting device 100 described above) shown in FIG. 16B is provided with an organic light emitting element 826 as an example of a light emitting element and a TFT 818 as an example of a transistor. A substrate 811 of glass, silicon, or the like is provided and an insulating layer 812 is provided on the substrate 811. The active element such as the TFT 818 is arranged on the insulating layer, and a gate electrode 813, a gate insulating film 814, and a semiconductor layer 815 of the active element are arranged. The TFT 818 further includes the semiconductor layer 815, a drain electrode 816, and a source electrode 817. An insulating film 819 is provided on the TFT 818. The source electrode 817 and an anode 821 forming the organic light emitting element 826 are connected via a contact hole 820 formed in the insulating film.

A method of electrically connecting the electrodes (anode and cathode) included in the organic light emitting element 826 and the electrodes (source electrode and drain electrode) included in the TFT is not limited to that shown in FIG. 16B. That is, one of the anode and cathode and one of the source electrode and drain electrode of the TFT are electrically connected. The TFT indicates a thin-film transistor.

In the display apparatus 800 shown in FIG. 16B, an organic compound layer is illustrated as one layer. However, an organic compound layer 822 may include layers. A first protection layer 824 and a second protection layer 825 are provided on a cathode 823 to suppress deterioration of the organic light emitting element.

A transistor is used as a switching element in the display apparatus 800 shown in FIG. 16B, but another switching element may be used instead.

The transistor used in the display apparatus 800 shown in FIG. 16B is not limited to a transistor using a single-crystal silicon wafer, and may be a thin-film transistor including an active layer on an insulating surface of a substrate. Examples of the active layer include single-crystal silicon, amorphous silicon, non-single-crystal silicon such as microcrystalline silicon, and a non-single-crystal oxide semiconductor such as indium zinc oxide and indium gallium zinc oxide. Note that a thin-film transistor is also called a TFT element.

The transistor included in the display apparatus 800 shown in FIG. 16B may be formed in the substrate such as a silicon substrate. Forming the transistor in the substrate means forming the transistor by processing the substrate such as a silicon substrate. That is, when the transistor is included in the substrate, it can be considered that the substrate and the transistor are formed integrally.

The light emission luminance of the organic light emitting element according to this embodiment can be controlled by the TFT which is an example of a switching element, and organic light emitting elements can be provided in a plane to display an image with the light emission luminances of the respective elements. Here, the switching element according to this embodiment is not limited to the TFT, and may be a transistor formed from low-temperature polysilicon or an active matrix driver formed on the substrate such as a silicon substrate. The term “on the substrate” may mean “in the substrate”. Whether to provide a transistor in the substrate or use a TFT is selected based on the size of the display unit. For example, if the size is about 0.5 inch, the organic light emitting element may be provided on the silicon substrate.

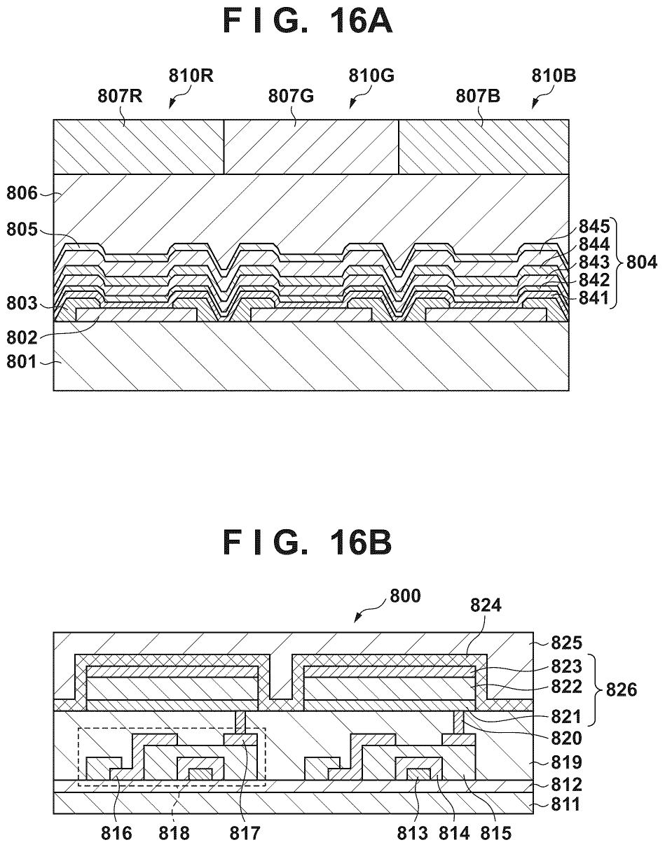

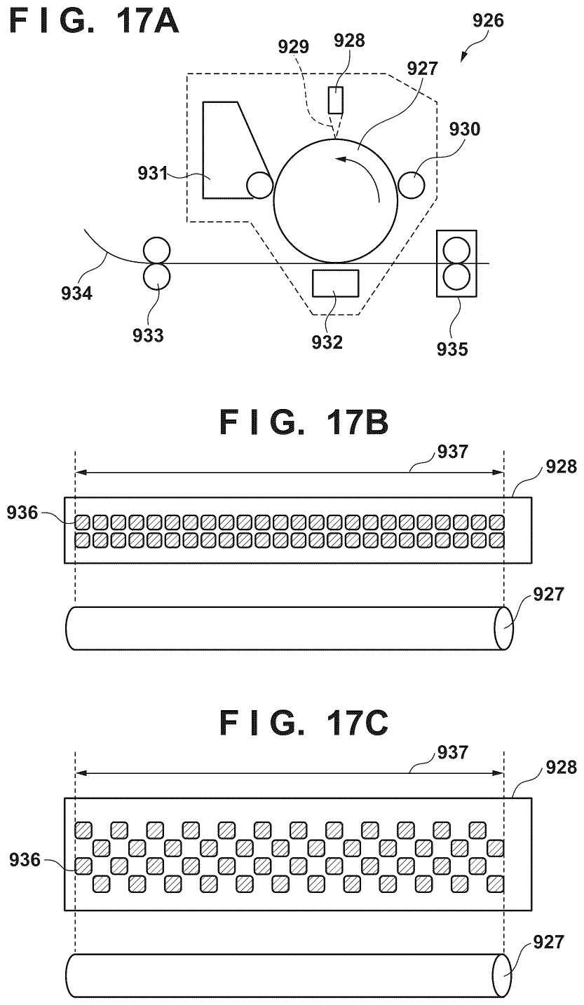

FIGS. 17A to 17C are schematic views showing an example of an image forming apparatus using the light emitting device 100 according to this embodiment. An image forming apparatus 926 shown in FIG. 17A includes a photosensitive member 927, an exposure light source 928, a developing unit 931, a charging unit 930, a transfer device 932, a conveyance unit 933 (a conveyance roller in the arrangement shown in FIG. 17A), and a fixing device 935.

Light 929 is emitted from the exposure light source 928, and an electrostatic latent image is formed on the surface of the photosensitive member 927. The light emitting device 100 can be applied to the exposure light source 928. The developing unit 931 can function as a developing device that includes a toner or the like as a developing agent and applies the developing agent to the exposed photosensitive member 927. The charging unit 930 charges the photosensitive member 927. The transfer device 932 transfers the developed image to a print medium 934. The conveyance unit 933 conveys the print medium 934. The print medium 934 can be, for example, paper, a film, or the like. The fixing device 935 fixes the image formed on the print medium.

Each of FIGS. 17B and 17C is a schematic view showing a form in which light emitting units 936 are arranged in the exposure light source 928 along the longitudinal direction of a long substrate. The light emitting device 100 can be applied to each of the light emitting units 936. That is, the pixels are arranged along the longitudinal direction of the substrate. A direction 937 is a direction parallel to the axis of the photosensitive member 927. This column direction matches the direction of the axis upon rotating the photosensitive member 927. This direction 937 can also be referred to as the long-axis direction of the photosensitive member 927.

FIG. 17B shows a form in which the light emitting units 936 are arranged along the long-axis direction of the photosensitive member 927. FIG. 17C shows a form, which is a modification of the arrangement of the light emitting units 936 shown in FIG. 17B, in which the light emitting units 936 are arranged in the column direction alternately between the first column and the second column. The light emitting units 936 are arranged at different positions in the row direction between the first column and the second column. In the first column, light emitting units 936 are arranged apart from each other. In the second column, the light emitting unit 936 is arranged at the position corresponding to the space between the light emitting units 936 in the first column. Furthermore, in the row direction, light emitting units 936 are arranged apart from each other. The arrangement of the light emitting units 936 shown in FIG. 17C can be referred to as, for example, an arrangement in a grid pattern, an arrangement in a staggered pattern, or an arrangement in a checkered pattern.

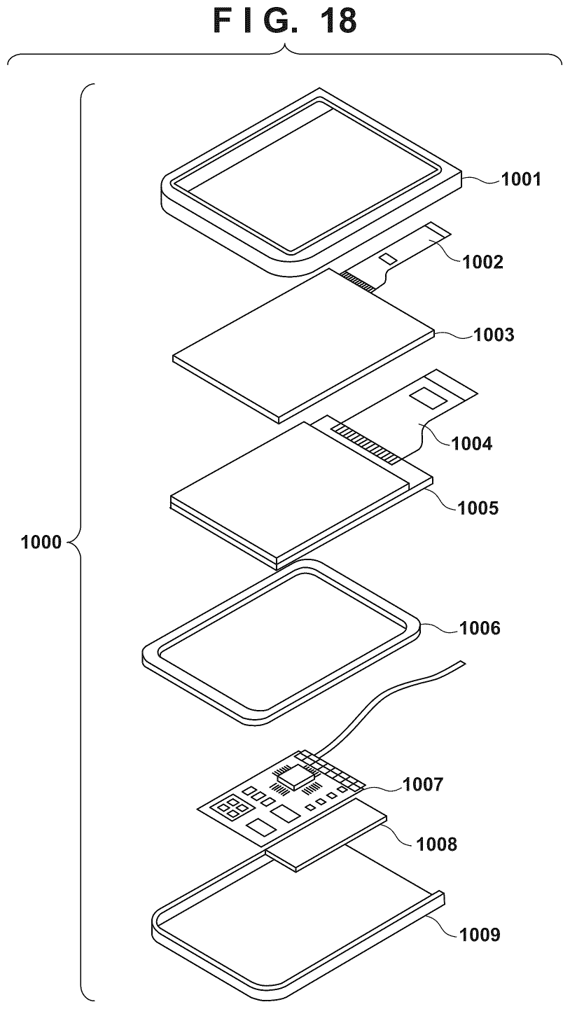

FIG. 18 is a schematic view showing an example of the display apparatus using the light emitting device 100 according to this embodiment. A display apparatus 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Active elements such as transistors are arranged on the circuit board 1007. The battery 1008 is unnecessary if the display apparatus 1000 is not portable equipment. Even when the display apparatus 1000 is portable equipment, the battery 1008 need not be provided at this position. The light emitting device 100 can be applied to the display panel 1005. The pixels PIX arranged in the light emitting device 100 functioning as the display panel 1005 are connected to the active element such as the transistor arranged on the circuit board 1007 and operate.

The display apparatus 1000 shown in FIG. 18 can be used for a display unit of a photoelectric conversion apparatus (also referred to as an image capturing apparatus) including an optical unit having lenses, and an image sensor for receiving light having passed through the optical unit and photoelectrically converting the light into an electric signal. The photoelectric conversion apparatus can include a display unit for displaying information acquired by the image sensor. In addition, the display unit can be either a display unit exposed outside the photoelectric conversion apparatus, or a display unit arranged in the finder. The photoelectric conversion apparatus can be a digital camera or a digital video camera.

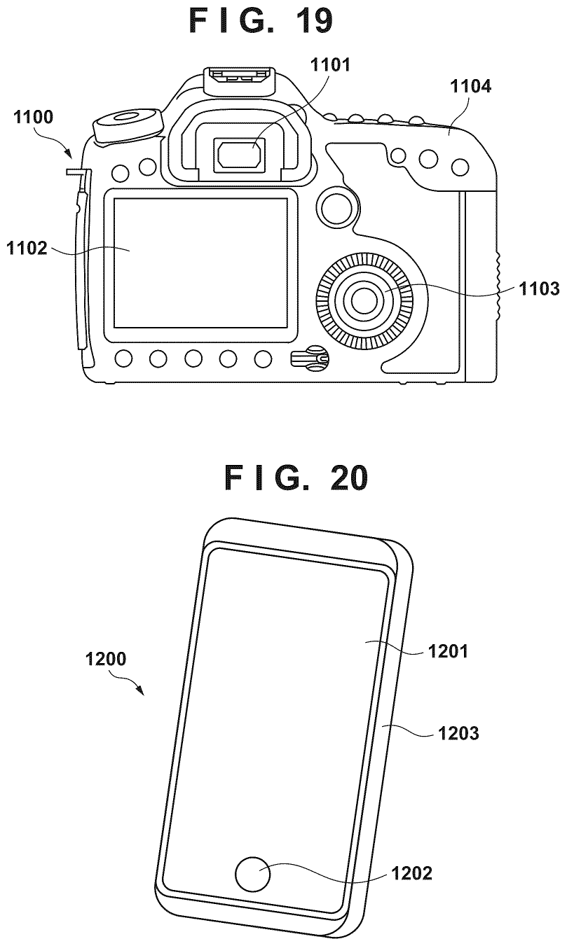

FIG. 19 is a schematic view showing an example of the photoelectric conversion apparatus using the light emitting device 100. A photoelectric conversion apparatus 1100 can include a viewfinder 1101, a rear display 1102, an operation unit 1103, and a housing 1104. The photoelectric conversion apparatus 1100 can also be called an image capturing apparatus. The light emitting device 100 can be applied to the viewfinder 1101 or the rear display 1102 as a display unit. In this case, the light emitting device 100 can display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time in many cases, it is better to display the information as soon as possible. Therefore, the light emitting device 100 in which the pixel including the light emitting element O using the organic light emitting material such as an organic EL element is arranged may be used for the viewfinder 1101 or the rear display 1102. This is so because the organic light emitting material has a high response speed. The light emitting device 100 using the organic light emitting material can be used for the apparatuses that require a high display speed more suitably than for the liquid crystal display apparatus.

The photoelectric conversion apparatus 1100 includes an optical unit (not shown). This optical unit has lenses, and forms an image on a photoelectric conversion element (not shown) that receives light having passed through the optical unit and is accommodated in the housing 1104. The focal points of lenses can be adjusted by adjusting the relative positions. This operation can also automatically be performed.

The light emitting device 100 may be applied to a display unit of electronic equipment. At this time, the display unit can have both a display function and an operation function. Examples of the portable terminal are a portable phone such as a smartphone, a tablet, and a head mounted display.

FIG. 20 is a schematic view showing an example of electronic equipment using the light emitting device 100 according to this embodiment. Electronic equipment 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit 1202 can also be a biometric authentication unit that performs unlocking or the like by authenticating the fingerprint. The portable equipment including the communication unit can also be regarded as communication equipment. The light emitting device 100 according to this embodiment can be applied to the display unit 1201.

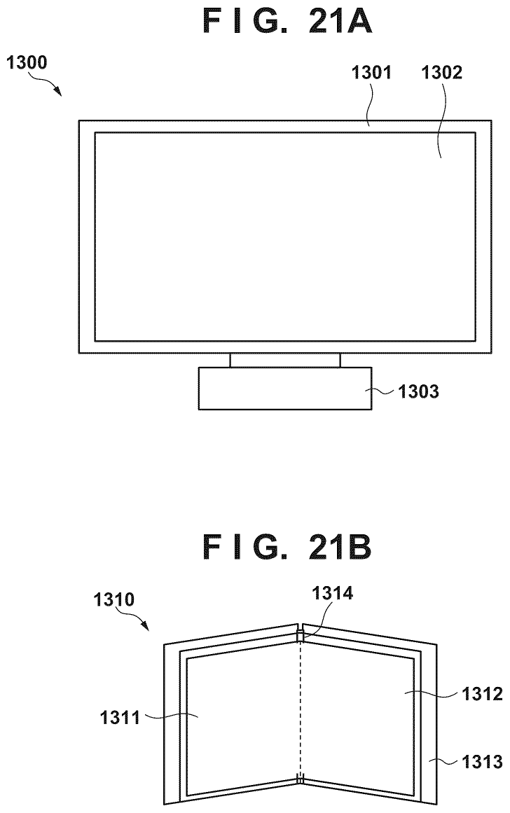

FIGS. 21A and 21B are schematic views showing examples of the display apparatus using the light emitting device 100 according to this embodiment. FIG. 21A shows a display apparatus such as a television monitor or a PC monitor. A display apparatus 1300 includes a frame 1301 and a display unit 1302. The light emitting device 100 according to this embodiment can be applied to the display unit 1302. The display apparatus 1300 can include a base 1303 that supports the frame 1301 and the display unit 1302. The base 1303 is not limited to the form shown in FIG. 21A. For example, the lower side of the frame 1301 may also function as the base 1303. In addition, the frame 1301 and the display unit 1302 can be bent. The radius of curvature in this case can be 5,000 mm (inclusive) to 6,000 mm (inclusive).

FIG. 21B is a schematic view showing another example of the display apparatus using the light emitting device 100 according to this embodiment. A display apparatus 1310 shown in FIG. 21B can be folded, and is a so-called foldable display apparatus. The display apparatus 1310 includes a first display unit 1311, a second display unit 1312, a housing 1313, and a bending point 1314. The light emitting device 100 according to this embodiment can be applied to each of the first display unit 1311 and the second display unit 1312. The first display unit 1311 and the second display unit 1312 can also be one seamless display apparatus. The first display unit 1311 and the second display unit 1312 can be divided by the bending point. The first display unit 1311 and the second display unit 1312 can display different images, and can also display one image together.

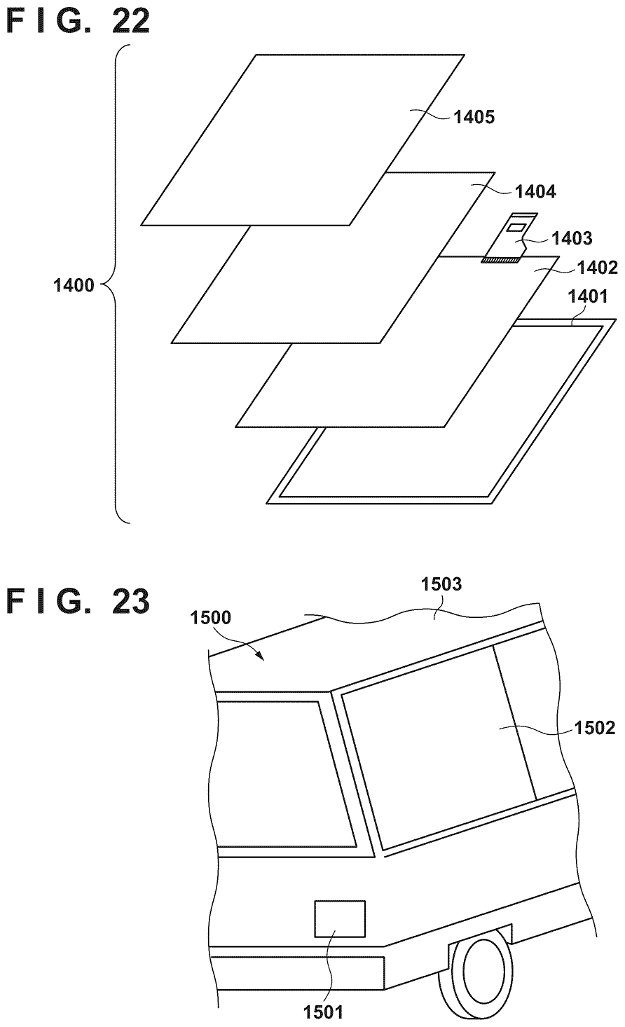

FIG. 22 is a schematic view showing an example of the illumination apparatus using the light emitting device 100 according to this embodiment. An illumination apparatus 1400 can include a housing 1401, a light source 1402, a circuit board 1403, an optical film 1404, and a light diffusing unit 1405. The light emitting device 100 according to this embodiment can be applied to the light source 1402. The optical film 1404 can be a filter that improves the color rendering of the light source. When performing lighting-up or the like, the light diffusing unit 1405 can throw the light of the light source over a broad range by effectively diffusing the light. The illumination apparatus can also include a cover on the outermost portion, as needed. The illumination apparatus 1400 can include both or one of the optical film 1404 and the light diffusing unit 1405.

The illumination apparatus 1400 is, for example, an apparatus for illuminating the interior of the room. The illumination apparatus 1400 can emit white light, natural white light, or light of any color from blue to red. The illumination apparatus 1400 can also include a light control circuit for controlling these light components. The illumination apparatus 1400 can also include a power supply circuit connected to the light emitting device 100 functioning as the light source 1402. The power supply circuit is a circuit for converting an AC voltage into a DC voltage. White has a color temperature of 4,200 K, and natural white has a color temperature of 5,000 K. The illumination apparatus 1400 may also include a color filter. In addition, the illumination apparatus 1400 can include a heat radiation unit. The heat radiation unit radiates the internal heat of the apparatus to the outside of the apparatus, and examples are a metal having a high specific heat and liquid silicon.

FIG. 23 is a schematic view of an automobile having a taillight as an example of a vehicle lighting appliance using the light emitting device 100 according to this embodiment. An automobile 1500 has a taillight 1501, and can have a form in which the taillight 1501 is turned on when performing a braking operation or the like. The light emitting device 100 according to this embodiment can be used as a headlight serving as a vehicle lighting appliance. The automobile is an example of a moving body, and the moving body may be a ship, a drone, an aircraft, a railroad car, an industrial robot, or the like. The moving body may include a main body and a lighting appliance provided in the main body. The lighting appliance may be used to make a notification of the current position of the main body.

The light emitting device 100 according to this embodiment can be applied to the taillight 1501. The taillight 1501 can include a protection member for protecting the light emitting device 100 functioning as the taillight 1501. The material of the protection member is not limited as long as the material is a transparent material with a strength that is high to some extent, and an example is polycarbonate. The protection member may be made of a material obtained by mixing a furandicarboxylic acid derivative, an acrylonitrile derivative, or the like in polycarbonate.

The automobile 1500 can include a vehicle body 1503, and a window 1502 attached to the vehicle body 1503. This window can be a window for checking the front and back of the automobile, and can also be a transparent display such as a head-up display. For this transparent display, the light emitting device 100 according to this embodiment may be used. In this case, the constituent materials of the electrodes and the like of the light emitting device 100 are formed by transparent members.

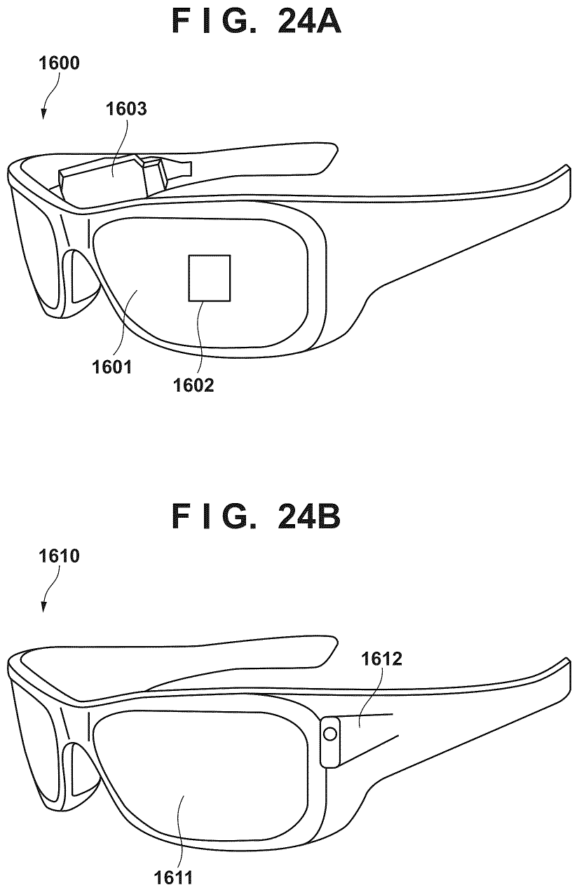

Further application examples of the light emitting device 100 according to this embodiment will be described with reference to FIGS. 24A and 24B. The light emitting device 100 can be applied to a system that can be worn as a wearable device such as smartglasses, a Head Mounted Display (HMD), or a smart contact lens. An image capturing display apparatus used for such application examples includes an image capturing apparatus capable of photoelectrically converting visible light and a light emitting apparatus capable of emitting visible light.

Glasses 1600 (smartglasses) according to one application example will be described with reference to FIG. 24A. An image capturing apparatus 1602 such as a CMOS sensor or an SPAD is provided on the surface side of a lens 1601 of the glasses 1600. In addition, the light emitting device 100 according to this embodiment is provided on the back surface side of the lens 1601.

The glasses 1600 further include a control apparatus 1603. The control apparatus 1603 functions as a power supply that supplies electric power to the image capturing apparatus 1602 and the light emitting device 100 according to each embodiment. In addition, the control apparatus 1603 controls the operations of the image capturing apparatus 1602 and the light emitting device 100. An optical system configured to condense light to the image capturing apparatus 1602 is formed on the lens 1601.

Glasses 1610 (smartglasses) according to one application example will be described with reference to FIG. 24B. The glasses 1610 include a control apparatus 1612, and an image capturing apparatus corresponding to the image capturing apparatus 1602 and the light emitting device 100 are mounted on the control apparatus 1612. The image capturing apparatus in the control apparatus 1612 and an optical system configured to project light emitted from the light emitting device 100 are formed in a lens 1611, and an image is projected to the lens 1611. The control apparatus 1612 functions as a power supply that supplies electric power to the image capturing apparatus and the light emitting device 100, and controls the operations of the image capturing apparatus and the light emitting device 100. The control apparatus 1612 may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The light emitting device 100 according to the embodiment of the present disclosure can include an image capturing apparatus including a light receiving element, and control a displayed image based on the line-of-sight information of the user from the image capturing apparatus.

More specifically, the light emitting device 100 decides a first visual field region at which the user is gazing and a second visual field region other than the first visual field region based on the line-of-sight information. The first visual field region and the second visual field region may be decided by the control apparatus of the light emitting device 100, or those decided by an external control apparatus may be received. In the display region of the light emitting device 100, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control apparatus of the light emitting device 100, or those decided by an external control apparatus may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the light emitting device 100, the image capturing apparatus, or an external apparatus. If the external apparatus holds the AI program, it is transmitted to the light emitting device 100 via communication.

When performing display control based on line-of-sight detection, smartglasses further including an image capturing apparatus configured to capture the outside can be applied. The smartglasses can display captured outside information in real time.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims priority to Japanese Patent Application No. 2024-088277, which was filed on May 30, 2024, and which is hereby incorporated by reference herein in its entirety.

What is claimed is:

1. A light emitting device that comprises, on a rectangular substrate having long sides in a row direction and short sides in a column direction, pixels arranged to form rows and columns and a scanning circuit, wherein
each of the pixels includes a light emitting element and a driving circuit configured to drive the light emitting element,
the scanning circuit includes data holding circuits provided so as to respectively correspond to the columns,
each data holding circuit includes memory circuits each configured to hold data for controlling the driving circuits arranged in the pixels in a corresponding column, and
the memory circuits in each data holding circuit include a first memory circuit and a second memory circuit arranged to align in the row direction.

2. The device according to claim 1, wherein in each of the columns, the driving circuits arranged in the pixels in a corresponding column are arranged to align in the column direction.

3. The device according to claim 1, wherein a length of the driving circuit in the row direction is larger than a length, in the row direction, of a memory circuit corresponding to the driving circuit among the memory circuits.

4. The device according to claim 1, wherein a circuit layout of the first memory circuit and a circuit layout of the second memory circuit are different from each other.

5. The device according to claim 1, wherein in a planar view, an outer edge shape of the first memory circuit and an outer edge shape of the second memory circuit are different from each other.

6. The device according to claim 1, wherein a length of an outer edge shape of the first memory circuit in the column direction and a length of an outer edge shape of the second memory circuit in the column direction are different from each other.

7. The device according to claim 1, wherein an aspect ratio obtained by dividing a length in the column direction by a length in the row direction, of an outer edge shape of the first memory circuit, and an aspect ratio obtained by dividing a length in the column direction by a length in the row direction, of an outer edge shape of the second memory circuit, are different from each other.

8. The device according to claim 1, wherein
the memory circuits in each data holding circuit include a first type memory circuit including the first memory circuit and a second type memory circuit including the second memory circuit,
a length of the first type memory circuit in the column direction is larger than a length of the second type memory circuit in the column direction, and
in each data holding circuit, the number of the first type memory circuits is smaller than the number of the second type memory circuits.

9. The device according to claim 8, wherein a length of an outer edge shape of the first type memory circuit in the row direction is smaller than a length of an outer edge shape of the second type memory circuit in the row direction.

10. The device according to claim 8, wherein an aspect ratio obtained by dividing a length in the column direction by a length in the row direction, of an outer edge shape of the first type memory circuit, is higher than an aspect ratio obtained by dividing a length in the column direction by a length in the row direction, of an outer edge shape of the second type memory circuit.

11. The device according to claim 8, wherein
the memory circuits in each data holding circuit further include a third memory circuit which is the second type memory circuit, and
the second memory circuit and the third memory circuit are arranged to align in the column direction, and the first memory circuit and the third memory circuit are arranged to align in the row direction.

12. The device according to claim 11, wherein
the memory circuits in each data holding circuit further include a fourth memory circuit which is the second type memory circuit, and
the second memory circuit, the third memory circuit, and the fourth memory circuit are arranged to align in the column direction, and the first memory circuit and the fourth memory circuit are arranged to align in the row direction.

13. The device according to claim 8, wherein
in each data holding circuit, the first memory circuit and each of a predetermined number of the second type memory circuits are arranged to align in the row direction, and the predetermined number of the second type memory circuits are arranged to align in the column direction, and
in a case where a length of an outer edge shape of the first memory circuit in the column direction is L1, and an interval between two second type memory circuits among the predetermined number of the second type memory circuits in the column direction is L2, a relationship expressed by L2<L1<L2×(the predetermined number)
is satisfied.

14. The device according to claim 1, wherein
the scanning circuit further includes a column selection circuit configured to select a holding circuit to write the data out of the data holding circuits, and
a data holding circuit corresponding to one of the columns is arranged between the driving circuit and the column selection circuit.

15. The device according to claim 14, wherein the column selection circuit is configured to simultaneously select at least two data holding circuits out of the data holding circuits.

16. The device according to claim 15, wherein the at least two data holding circuits include data holding circuits provided corresponding to adjacent columns among the columns.

17. The device according to claim 1, wherein
the data holding circuits include a first data holding circuit and a second data holding circuit provided corresponding to adjacent columns among the columns, and
in a planar view, elements arranged in the memory circuits in the first data holding circuit and elements arranged in the memory circuits in the second data holding circuit are arranged at line-symmetric positions with respect to a virtual line passing through a boundary between the first data holding circuit and the second data holding circuit.

18. The device according to claim 1, wherein the driving circuit includes a first transistor configured to control a current flowing through the light emitting element, and a second transistor whose control terminal is supplied with a signal corresponding to the data, and configured to control one of light emission and non-light emission of the light emitting element.

19. The device according to claim 1, wherein
in each data holding circuit, transistors constituting each of the memory circuits are arranged, and
the transistors are arranged to cause a current to flow in the row direction in a channel region.

20. The device according to claim 19, wherein the transistors are all transistors constituting each of the memory circuits.

21. An image forming apparatus comprising a photosensitive member, an exposure light source configured to expose the photosensitive member, a developing device configured to apply a developing agent to the exposed photosensitive member, and a transfer device configured to transfer an image developed by the developing device to a print medium,
wherein the exposure light source includes the light emitting device according to claim 1.
